(19) United States
(12) Patent Application Publication
(10) Pub. No.: US 2010/0070214 A1
(43) Pub. Date: Mar. 18, 2010

(54) System and method for identifying appliances by electrical characteristics

(75) Inventors: Roderick A. Hyde, Redmond, WA (US); Jordin T. Kare, Seattle, WA (US); Lowell L. Wood, JR., Bellevue, WA (US)

Correspondence Address: SEARETE LLC;CLARENCE T. TEGREENE, 1756 - 114TH AVE., S.E., SUITE 110, BELLEVUE, WA, 98004, US

(73) Assignee: Searete LLC, a limited liability corporation of the State of Delaware

(21) Appl. No.: 12/290,631

(22) Filed: Oct. 30, 2008

Related U.S. Application Data
(63) Continuation-in-part of application No. 12/284,333, filed on Sep. 18, 2008.

(51) Int. Cl. G01R 21/00

(52) U.S. Cl. 702/61

(57) ABSTRACT

Illustrative embodiments provide systems, applications, apparatuses, computer software program products, and methods related to identification of electrical appliances by electrical characteristics.

### BACKGROUND

The present application relates to electrical appliances and systems, applications, apparatuses, computer software program products, and methods related thereto.

### SUMMARY

Illustrative embodiments provide systems, applications, apparatuses, computer software program products, and methods related to identification of electrical appliances by electrical characteristics.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIG. 1 illustrates generation, distribution, and monitoring of electrical power to a facility with electrical appliances.

FIG. 2A is a block diagram of an illustrative system.

FIG. 2B is a block diagram of the system of FIG. 2A with optional features.

FIGS. 3A through 3G are block diagrams of details of illustrative data processing systems.

FIG. 4A is a is a block diagram of another illustrative system for monitoring electrical appliances.

FIG. 4B is a block diagram of the system of FIG. 4A with optional features.

FIG. 5A is a block diagram of an illustrative system.

FIG. 5B is a block diagram of the system of FIG. 5A with optional features.

FIG. 6A is a block diagram of an illustrative system.

FIG. 6B is a block diagram of the system of FIG. 6A with optional features.

FIG. 7A is a block diagram of an illustrative system.

FIG. 7B is a block diagram of the system of FIG. 7A with optional features.

FIG. 8A is a block diagram of an illustrative system.

FIG. 8B is a block diagram of the system of FIG. 8A with optional features.

FIG. 9A is a block diagram of an illustrative system.

FIG. 9B is a block diagram of the system of FIG. 9A with optional features.

FIG. 10A is a block diagram of an illustrative system.

FIG. 10B is a block diagram of the system of FIG. 10A with optional features.

FIG. 11A is a flowchart of an illustrative method for identifying change in operational state of an electrical appliance.

FIGS. 11B through 11M are flowcharts of details of the method of FIG. 11A.

FIG. 12A is a flowchart of an illustrative method for identifying and monitoring change in operational state of an electrical appliance.

FIGS. 12B through 12J are flowcharts of details of the method of FIG. 12A.

FIG. 13A is a flowchart of an illustrative method for identifying change in operational state of an electrical appliance and for identifying an electrical appliance.

FIGS. 13B through 13G are flowcharts of details of the method of FIG. 13A.

FIG. 14A is a flowchart of another illustrative method for identifying change in operational state of an electrical appliance.

FIGS. 14B through 14M are flowcharts of details of the method of FIG. 14A.

FIG. 15A is a flowchart of another illustrative method for identifying change in operational state of an electrical appliance.

FIGS. 15B through 15M are flowcharts of details of the method of FIG. 15A.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

By way of overview, illustrative embodiments provide systems, applications, apparatuses, computer software program products, and methods related to identification of electrical appliances by electrical characteristics. For example, in various embodiments a change in operational state of an electrical appliance and/or identity of an electrical appliance may be identified, and/or monitored, and/or communicated.

Illustrative Environment

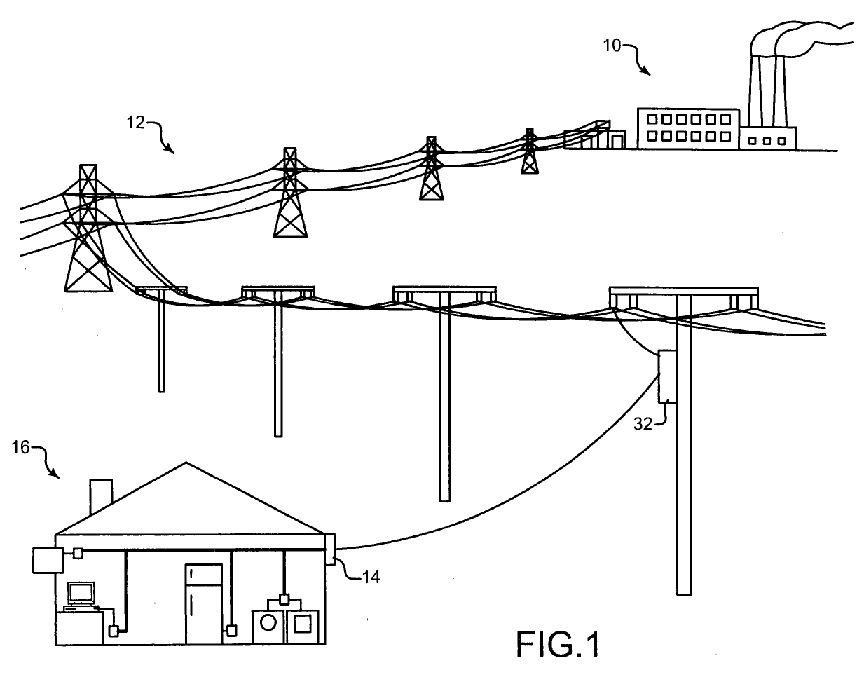

Still by way of overview and referring to FIG. 1, an illustrative, non-limiting environment will be explained in which embodiments may identify, monitor, and communicate identification data related to electrical appliances. In the non-limiting environment illustrated in FIG. 1, electrical power is generated at an electrical power generating facility 10 and distributed via distribution lines 12 to a service entrance 14 of a facility 16. Electrical appliances 18 within the facility 16 may be energized by electricity distributed within the facility 16 via electrical circuits 20 that are fed by the service entrance 14.

Given by way of example and not limitation, in some embodiments the facility 16 may be a residential facility, such as a house, townhouse, condominium, apartment, dormitory, or the like. In some other embodiments, the facility 16 may be a commercial facility, an industrial facility, an educational facility, a healthcare facility, a government facility, a military facility, or the like. Thus, the type of facility is not to be limited in any manner whatsoever.

The electrical appliances 18 may include any type of electrical appliance as desired for use in the applicable facility 16. Given by way of illustration and not limitation, illustrative examples of the electrical appliances 18 may include a resistive load such as a computer 18a, and inductive loads such as an air conditioner 18b, a refrigerator/freezer 18c, a washing machine 18d, and a dryer 18e.

The electrical appliance 18 may have any one of several operational states that are characterized by electrical load characteristics of the electrical appliance 18. The electrical load characteristics may include one or more components of electrical power, such as real power and/or reactive power, and/or one or more components of admittance, such as conductance and/or susceptance. For example, the electrical appliance 18 may have an operational state characterized by any amount of any one or more of the electrical load characteristics, such as real power, reactive power, conductance, and/or susceptance. As a further example, the electrical appliance 18 may be electrically disconnected (for example, unplugged) and off, or electrically connected (for example, plugged in) and off.

In the illustrative facility 16, the electrical circuits 20 supply electrical power from the service entry 14 (such as a distribution box or circuit breaker box) to outlets 22. The electrical appliances 18 are energized from the outlets 22. However, in some embodiments the electrical appliances 18 may be energized directly from the service entry 14.

Now that an illustrative environment has been explained, details of non-limiting embodiments will be explained.

Illustrative Systems

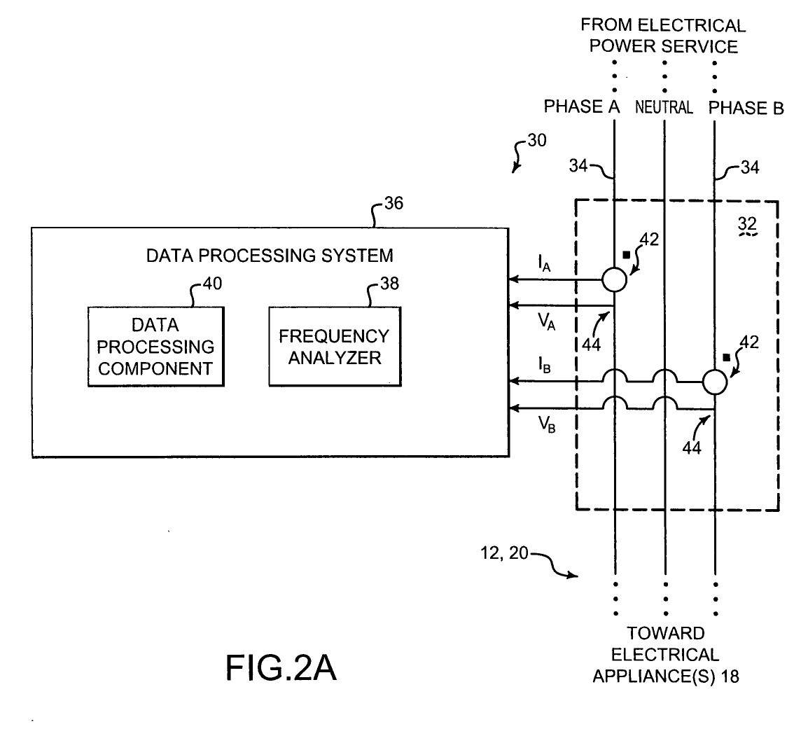

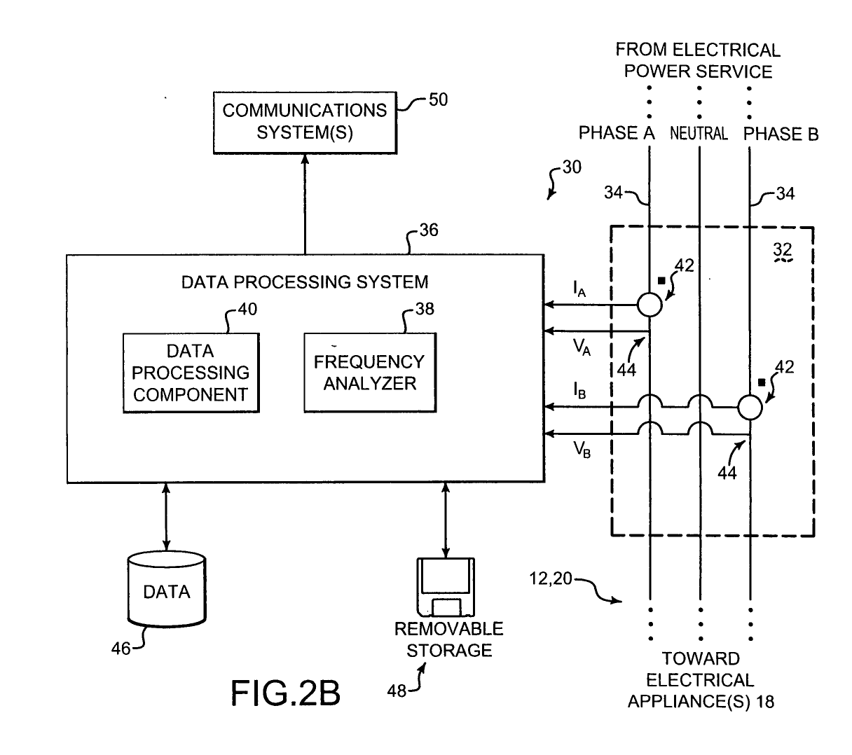

Referring additionally to FIG. 2A and by way of overview, an illustrative system 30 can identify at least one change in operational state of at least one of the electrical appliances 18. A measurement device 32 measures, at first and second times t₁ and t₂, electrical power signals 34 of one or more of the electrical circuits 20. A data processing system 36 includes a frequency analyzer 38 that frequency analyzes electrical signals that are indicative of the electrical power signals 34 measured at the times t₁ and t₂. The data processing system 36 also includes a data processing component 40 that can identify at least one change in operational state of at least one electrical appliance 18 based upon a difference in the frequency analyzed electrical signals. Illustrative details will now be set forth below.

The measurement device 32 can be located in any location as desired along the transmission path of electrical power toward the electrical appliances 18. It will be appreciated that, in general, measuring closer along the transmission path of electrical power to the electrical appliances 18 may result in a lower number of electrical appliances 18 that may be available for identification and/or monitoring. Conversely, in general, measuring closer along the transmission path of electrical power to the electrical power generation facility 10 may result in a greater number of electrical appliances 18 that may be available for identification and/or monitoring.

To that end, in some embodiments the measurement device 32 may be disposed at a location within the electrical circuit 20. Given by way of non-limiting examples, the measurement device 32 may be located at or near the outlet 22. However, the measurement device 32 can be located anywhere within the electrical circuit 20 as desired.

In some other embodiments, measurement devices 32 may be disposed as desired on different electrical circuits 20 with suitable frequency isolation between the electrical circuits 20. In such an arrangement, the measurement devices 32 can be functionally de-coupled at circuit breakers (not shown for clarity) for the electrical circuits 20.

In some other embodiments, the measurement device 32 may be disposed at a location that is electrically proximate to an isolation-point of the electrical circuit 20. For example, the measurement device 32 may be located near a circuit breaker (not shown for clarity) for the electrical circuit 20.

In some embodiments, the measurement device 32 may be disposed at the service entrance 14. In some other embodiments, the measurement device 32 may be disposed along the distribution line 12 between the electrical power generation facility 10 and the service entrance 14.

In measuring the electrical power signals 34, the measurement device 32 can measure current and voltage. To that end, the measurement device 32 includes at least one current measurement device 42. The current measurement devices 42 output signals I_{A} and I_{B} that are measurement signals indicative of the electrical current of phase A and the electrical current of phase B, respectively. The signals I_{A} and I_{B} may be analog signals or digital signals, depending upon the construction of the current measurement device 42. The current measurement device 42 can be any suitable current measurement device as desired for a particular application. For example, in some embodiments the current measurement device 42 can include a current transformer. In some other embodiments, the current measurement device 42 can include an ammeter, such as without limitation a non-contact ammeter like an ammeter clamp or the like.

The measurement device 32 also includes at least one voltage measurement device 44. The voltage measurement devices 44 output signals V_{A} and V_{B} that are measurement signals indicative of the voltage of phase A with respect to neutral and the voltage of phase B with respect to neutral, respectively. The signals V_{A} and V_{B} may be analog signals or digital signals, depending upon the construction of the voltage measurement device 44. The voltage measurement device 44 can be any suitable voltage measurement device as desired for a particular application. For example, in some embodiments the voltage measurement device 44 can include without limitation a test lead or probe, such as a non-contact voltage probe or the like.

In some embodiments the data processing component 36 receives the signals I_{A}, V_{A}, I_{B}, and V_{B} from the measurement device 32. The signals I_{A}, V_{A}, I_{B}, and V_{B} may be formatted, conditioned, and/or pre-processed as desired by the data processing system 36. For example, in some embodiments when the signals I_{A}, V_{A}, I_{B}, and V_{B} are analog signals, the data processing system 36 performs an analog-to-digital conversion of the signals I_{A}, V_{A}, I_{B}, and V_{B}. In some embodiments when the signals I_{A}, V_{A}, I_{B}, and V_{B} are digital signals, the data processing system 36 may also perform signal acquisition, handshaking, conditioning, and/or formatting processes as desired.

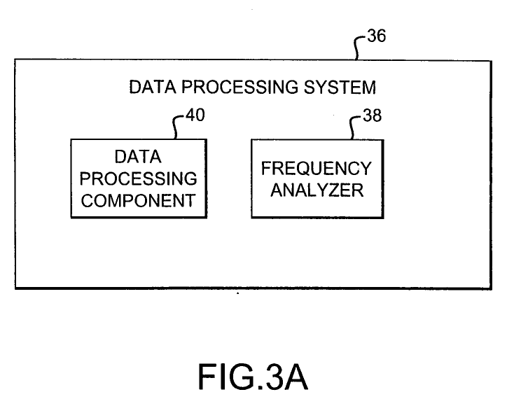

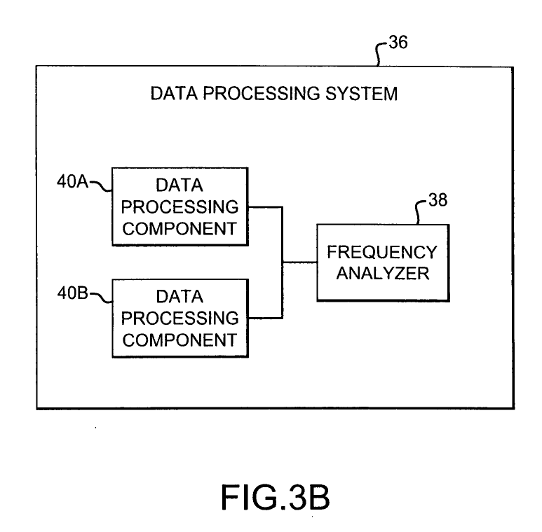

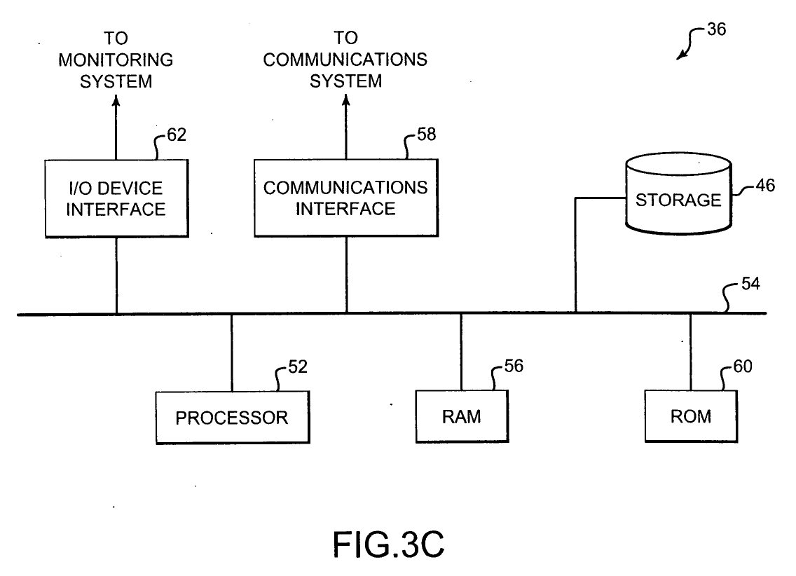

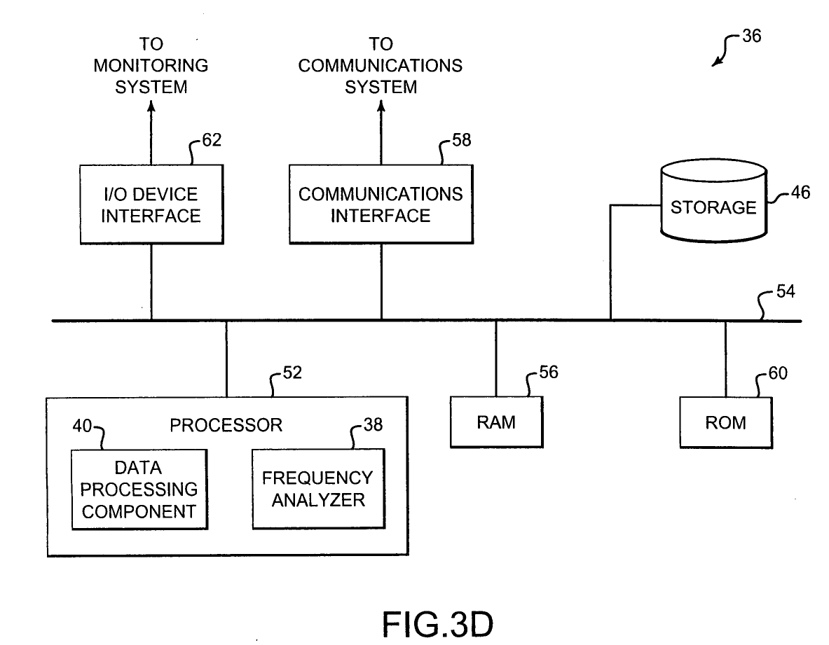

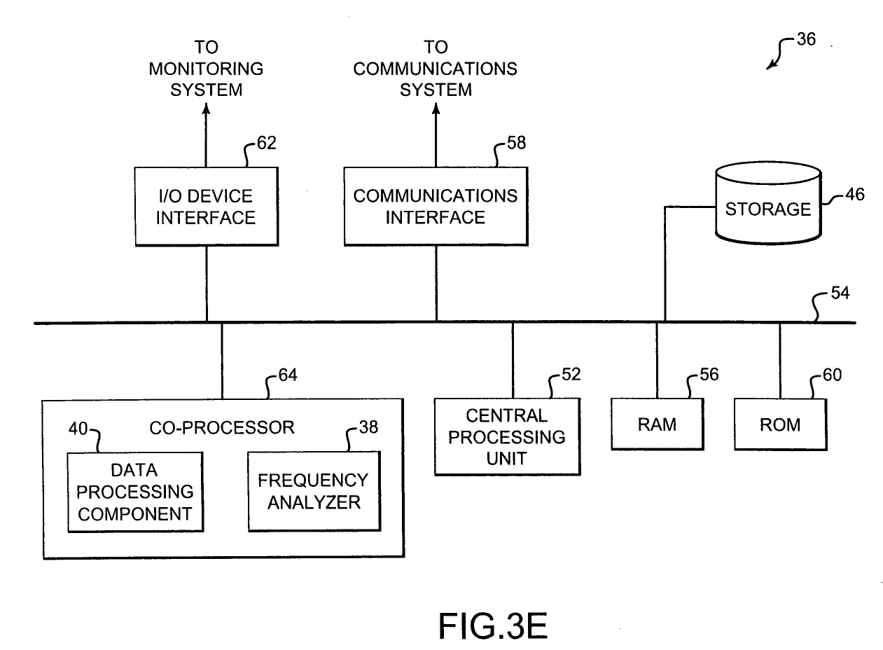

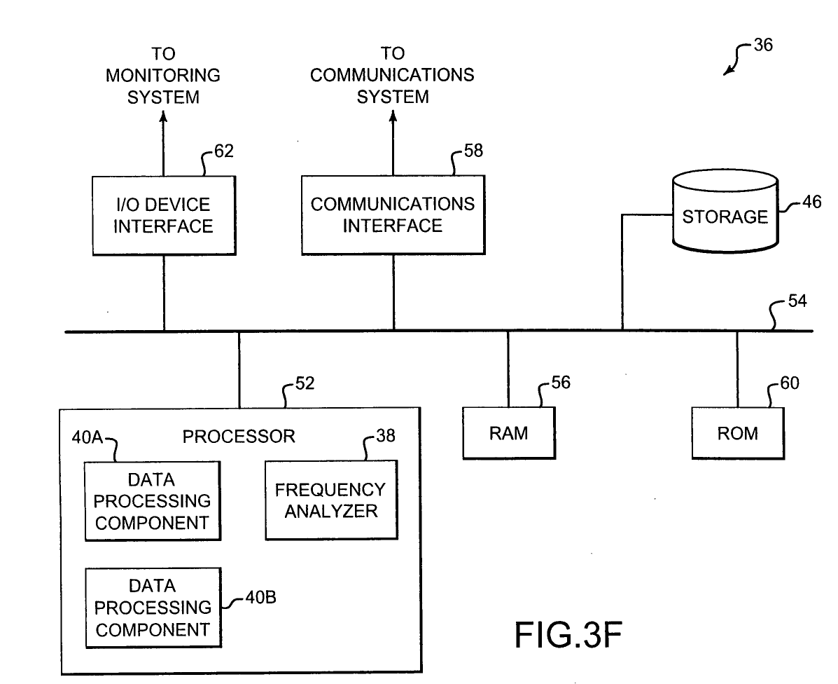

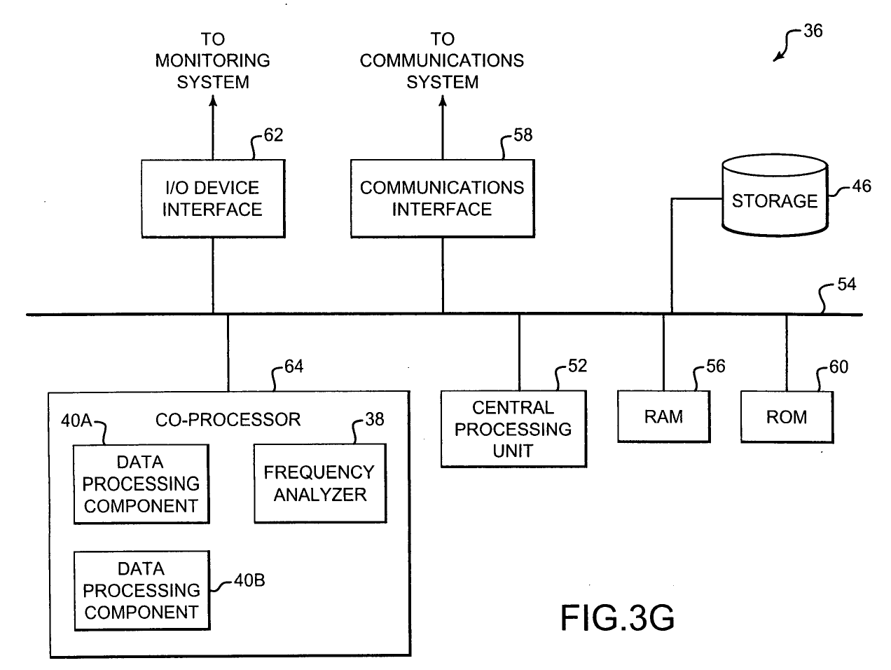

Referring additionally to FIG. 3A, in the data processing system 36 the frequency analyzer 38 and the data processing component 40 cooperate to analyze and process electrical signals that are indicative of measurements of the electrical power signals 34. In general, the frequency analyzer 38 frequency analyzes electrical signals that are indicative of the electrical power signals 34 measured at the times t₁ and t₂ and the data processing component 40 can identify at least one change in operational state of at least one electrical appliance 18 based upon a difference in the frequency analyzed electrical signals.

In some embodiments, the data processing component 40 can also identify the electrical appliances 18 based upon the difference in the frequency analyzed electrical signals. In such an arrangement, a comparison is made between the frequency analyzed electrical signals and predetermined frequency analyzed electrical signals for electrical appliances. Referring briefly to FIG. 2B, in some embodiments, the predetermined frequency analyzed electrical signals for electrical appliances may be stored in suitable data storage 46.

Referring back to FIGS. 2A and 3A, in some embodiments, the data processing component 40 can be configured to identify at least one change in operational state of at least one electrical appliance 18 based upon a difference in the frequency analyzed electrical signals and can be further configured to identify at least one change in operational state of at least one electrical appliance 18 based upon a difference in the frequency analyzed electrical signals.

In some other embodiments and referring additionally to FIG. 3B, processing can be performed by separate data processing components 40A and 40B. In such arrangements, the data processing component 40A is configured to identify at least one change in operational state of at least one electrical appliance 18 based upon a difference in the frequency analyzed electrical signals and the data processing component 40B is configured to identify at least one change in operational state of at least one electrical appliance 18 based upon a difference in the frequency analyzed electrical signals.

The data processing components 40A and 40B need not be physically separate data processing components. However, in some embodiments the data processing components 40A and 40B can be physically separate data processing components, if desired.

The frequency analyzer 38 frequency analyzes electrical signals that are indicative of the electrical power signals 34 measured at the times t₁ and t₂. In some embodiments the electrical signals that are indicative of the electrical power signals 34 may be the measured signals I_{A}, V_{A}, I_{B}, and V_{B}. In this arrangement, the frequency analyzer 38 frequency analyzes at least one of the signals I_{A}, V_{A}, I_{B}, and V_{B} (either as-received or pre-processed as described above, as desired).

In some other embodiments the electrical signals that are indicative of the electrical power signals 34 may be calculated parameter signals that are calculated from the measured signals I_{A}, V_{A}, I_{B}, and V_{B}. The calculated parameters suitably are calculated by any data processing component of the data processing system 36 (such as without limitation the data processing component 40, 40A, 40B, or any other data processing component). The calculated parameters suitably are electrical load characteristics, as described above. In such arrangements, the frequency analyzer 38 can frequency analyze any one or more of real power, reactive power, conductance, and/or susceptance.

The frequency analyzer 38 can analyze various frequency components. In some embodiments, the frequency analyzer 38 analyzes the fundamental frequency component of the electrical signals that are indicative of the electrical power signals 34.

In some other embodiments, the frequency analyzer 38 analyzes at least one non-fundamental harmonic frequency component of the electrical signals that are indicative of the electrical power signals 34 (either in addition to the fundamental frequency or in lieu of the fundamental frequency). In such an arrangement, the at least one non-fundamental harmonic frequency component can include at least one odd non-fundamental harmonic frequency component. Analysis of at least one odd non-fundamental harmonic frequency component may be desirable because, in general, odd harmonics of the measured or calculated parameters may be more prominent than even harmonics of the measured or calculated parameters. In particular, it may be desirable that the odd non-fundamental harmonic frequency component include the third harmonic frequency component of the measured or calculated parameter because the third harmonic frequency component may have values that are larger than values for other non-fundamental harmonic frequency components. However, as discussed above, it will be appreciated that the frequency components need not be just non-fundamental harmonic frequency components.

The frequency analyzer 38 suitably performs any frequency analysis technique as desired for a particular application. Given by way of non-limiting example, in some embodiments the frequency analyzer 38 performs a Fourier transformation, such as without limitation a fast Fourier transform, of the electrical signals that are indicative of the electrical power signals 34 measured at the times t₁ and t₂. However, the frequency analyzer 38 can perform any type of frequency analysis as desired for a particular application.

In some embodiments, if desired, the frequency analyzer 38 may filter out transients (e.g., start up of a compressor motor or similar load transient). In some other embodiments, if desired, the frequency analyzer 38 may combine spectral analysis with startup/transient signal analysis as part of identifying at least one change in operational state of at least one electrical appliance 18 or identifying at least one electrical appliance 18.

The frequency analyzer 38 may be implemented in any suitable manner as desired for a particular application. For example, in some embodiments the frequency analyzer 38 may be implemented as suitable signal processing computer software executing on a processing component of the data processing system 36 or on a separate computer processor. In some other embodiments, the frequency analyzer 38 may be implemented as a hardware device that may be separate from the data processing system 36 or part of the data processing system 36, as desired for a particular application.

Referring now to FIG. 2B, the system 30 may include optional features, if desired. For example, in some embodiments the data indicative of the at least one change in operational state of at least one electrical appliance 18 optionally may be stored in suitable data storage 48. In embodiments in which the electrical appliances 18 can be identified, the data indicative of identity of the identified appliances may be stored in the data storage 48. If desired, in some embodiments the data storage 48 may be removable. Data stored in the data storage 48 may be accessed as desired. Given by way of non-limiting example, when the data storage 48 is provided at a service entrance, the data storage may be removed upon meter-reading for accessing of the data stored therein.

In some embodiments, if desired the system 30 may include a communications system 50 that is configured to communicate the data indicative of the at least one change in operational state of at least one electrical appliance 18. In embodiments in which the electrical appliances 18 can be identified, the data indicative of identity of the identified appliances may be communicated by the communications system 50. The data may be communicated by the communications system 50 from the location of the system 30 to any other location as desired for a particular application. Illustrative applications of communicated data are discussed further below.

The communications system 50 may be any suitable communication system that uses any type of communications format as desired for a particular application. Given by way of example and not limitation, the communications system 50 may include any communications system such as a power line carrier communication system, a wireless communication system, a network communication system, or the like.

Further illustrative details regarding the data processing system 30 will now be discussed. Referring now to FIG. 3C, typical computing system components used in an illustrative data processing system 36 include a processor 52, such as a central processing unit (“CPU”) (or microprocessor) connected to a system bus 54. Random access main memory (“RAM”) 56 is coupled to the system bus 66 and provides the processor 52 with access to the data storage 58. When executing program instructions, the processor 52 stores those process steps in the RAM 56 and executes the stored process steps out of the RAM 56.

The data processing system 36 can connect to the communications system 50 (not shown in FIG. 3C), when provided, via a communications interface 58.

Read only memory (“ROM”) 60 is provided to store invariant instruction sequences such as start-up instruction sequences or basic input/output operating system (BIOS) sequences.

An Input/Output (“I/O”) device interface 62 allows the data processing system 36 to connect to various input/output devices, for example, a keyboard, a pointing device (e.g., “mouse”), a monitor, printer, a modem, a monitoring system (if provided), and the like. The I/O device interface 62 is shown as a single block for simplicity and may include several interfaces to interface with different types of I/O devices.

It will be appreciated that embodiments are not limited to the architecture of the data processing system 36 shown in FIG. 3C. Based on the type of applications/business environment, the data processing system 36 may have more or fewer components. For example, the data processing system 36 can be any type of computing system, such as without limitation a set-top box, a lap-top computer, a notebook computer, a desktop system, a palm-top computer, or any other type of computing system whatsoever.

Given by way of non-limiting example and referring now to FIG. 3D, in some embodiments the processor 52 can include the frequency analyzer 38 and the data processing component 40 as described above with reference to FIG. 3A.

In some other embodiments and referring now to FIG. 3E, a co-processor 64 can include the frequency analyzer 38 and the data processing component 40. In such an arrangement, the processor 52 can function as a central processing unit. The co-processor 64 can be dedicated to performing processing functions related to the frequency analyzer 38 and the data processing component 40. The processor 52, functioning as a central processing unit, can perform all other processing related to overhead functions, communications, pre-processing, signal conditioning, and the like.

In some embodiments and referring now to FIG. 3F, the processor 52 can include the frequency analyzer 38 and the data processing components 40A and 40B as described above with reference to FIG. 3B. In some other embodiments and referring now to FIG. 3G, the co-processor 64 can include the frequency analyzer 38 and the data processing components 40A and 40B. In such an arrangement, the processor 52 can function as a central processing unit and the co-processor 64 can be dedicated to performing processing functions related to the frequency analyzer 38 and the data processing components 40A and 40B.

Additional illustrative systems will now be discussed below.

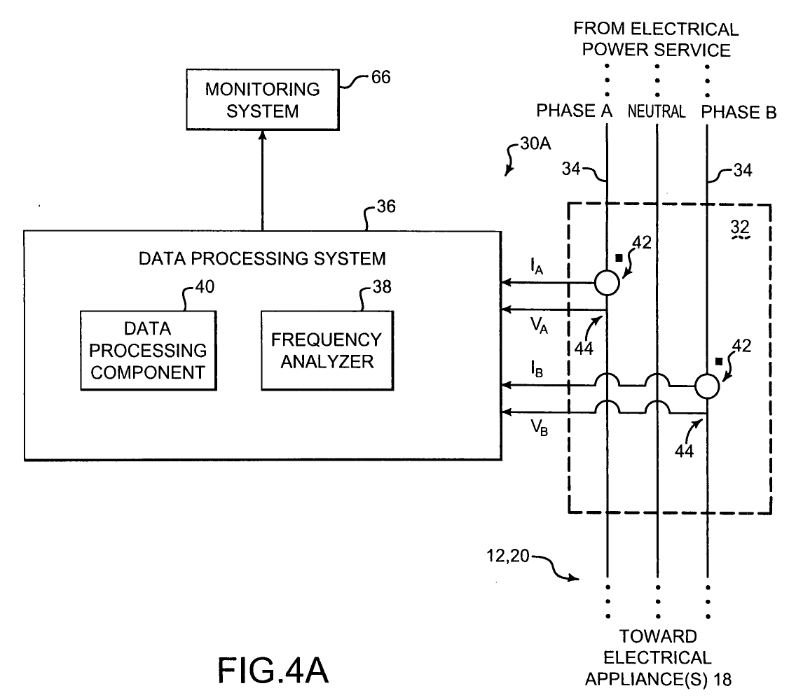

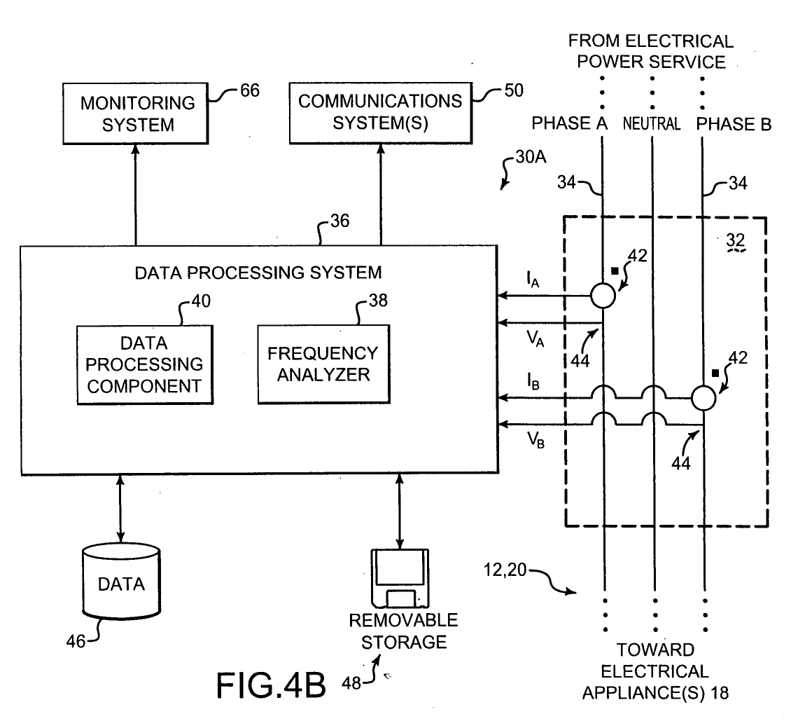

Referring now to FIG. 4A, a system 30A can monitor data indicative of the at least one change in operational state of at least one of the electrical appliances 18. Other features of the system 30A are similar to features of the system 30 (FIG. 2A) and need not be repeated for sake of brevity. A monitoring system 66 is operatively coupled to the data processing system 36 to receive the data indicative of the at least one change in operational state of at least one of the electrical appliances 18. The monitoring system 66 suitably may be operatively coupled to the data processing system 36 via the I/O device interface 62 (FIGS. 3C-3G).

The monitoring system 66 can include any type of monitoring device as desired for a particular application. Given by way of example and not of limitation, the monitoring system 66 can include a suitable visual monitor, such as a liquid crystal display, a plasma display, a cathode ray tube, or the like. The monitoring system 66 can also include indicator lights, such as incandescent lamps or liquid crystal diodes or the like, to indicate operational states, such as on or off. The monitoring system 66 can also include a suitable hard-copy output device, such as a printer or the like. In addition to visual indication as described above, the monitoring system 66 can include any suitable audio output device, such as a loudspeaker or a headset or headphones the like, that can audibly indicate an operational state, as desired.

Referring now to FIG. 4B, the system 30A may include optional features, if desired, such as any one or more of those discussed with reference to FIG. 2B. For example, in some embodiments the data indicative of the at least one change in operational state of at least one electrical appliance 18 optionally may be stored in the data storage 48. Also, in embodiments in which the electrical appliances 18 can be identified, the predetermined frequency analyzed electrical signals for predetermined electrical appliances may be stored in the data storage 46 and the data indicative of identity of the identified appliances may be stored in the data storage 48. If desired, in some embodiments the data storage 48 may be removable. Further, if desired the system 30 may include the communications system 50 that is configured to communicate the data indicative of the at least one change in operational state of at least one electrical appliance 18. In embodiments in which the electrical appliances 18 can be identified, the data indicative of identity of the identified appliances may be communicated by the communications system 50.

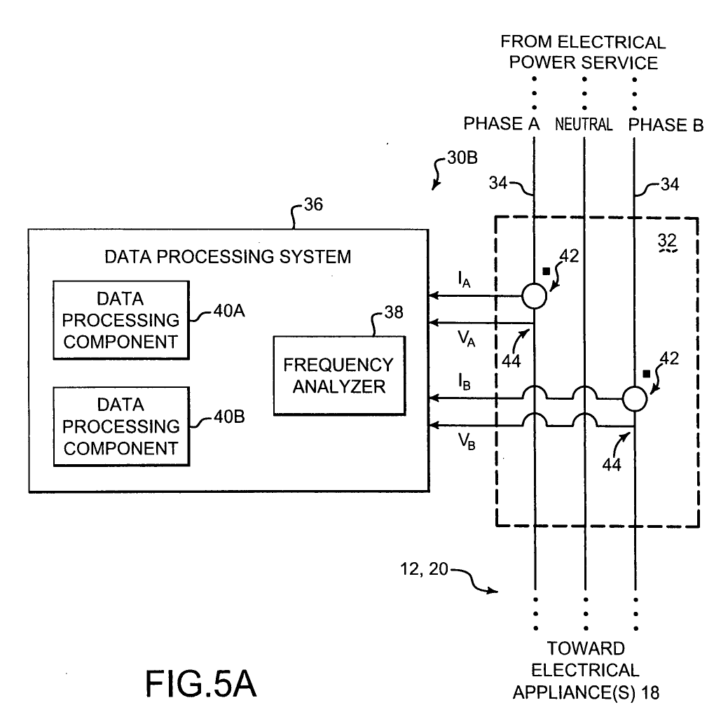

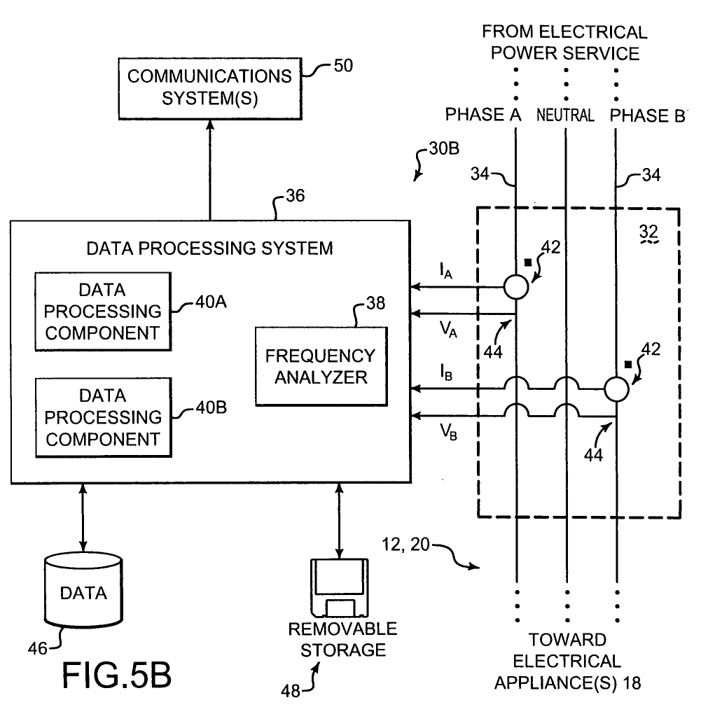

Referring now to FIG. 5A, a system 30B can identify at least one change in operational state of at least one of the electrical appliances 18 and can identify the electrical appliances 18. To that end, the data processing system 36 includes the data processing components 40A and 40B. Other features of the system 30B are similar to features of the system 30 (FIG. 2A) and need not be repeated for sake of brevity.

Referring now to FIG. 5B, the system 30B may include optional features, if desired, such as any one or more of those discussed with reference to FIG. 2B. For example, in some embodiments the predetermined frequency analyzed electrical signals for predetermined electrical appliances may be stored in the data storage 46 and the data indicative of the at least one change in operational state of at least one electrical appliance 18 optionally may be stored in the data storage 48. Also, the data indicative of identity of the identified appliances may be stored in the data storage 48. If desired, in some embodiments the data storage 48 may be removable. Further, if desired the system 30B may include the communications system 50. When provided for the system 30B, the communications system 50 can be configured to communicate the data indicative of the at least one change in operational state of at least one electrical appliance 18 and/or the data indicative of identity of the identified appliances.

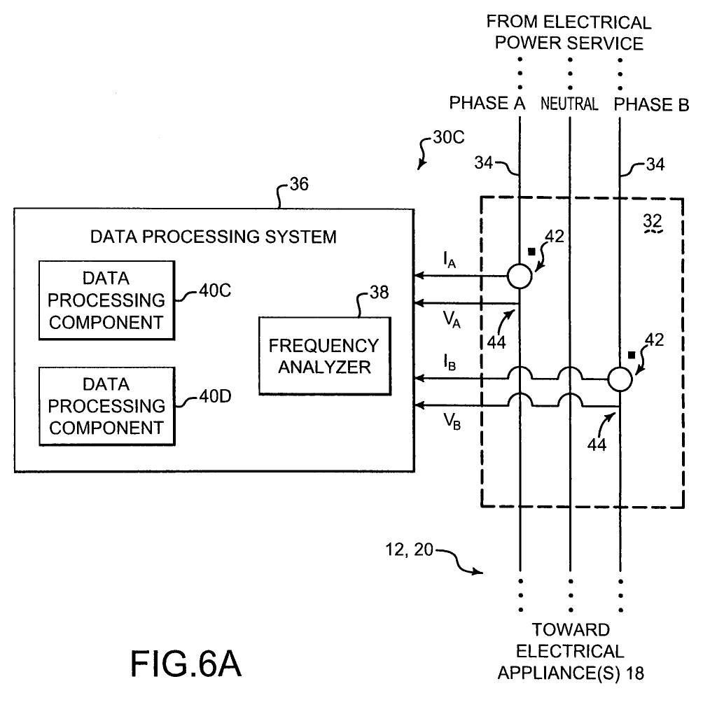

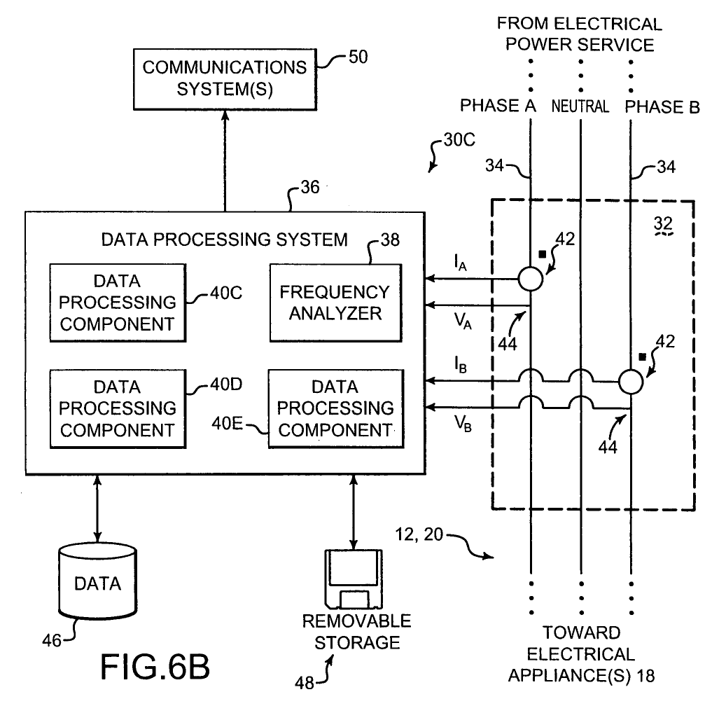

Referring now to FIG. 6A, a system 30C can identify at least one change in operational state of at least one of the electrical appliances 18. To that end, the data processing system 36 includes the frequency analyzer 38 that is configured to frequency analyze the measured electrical power signals as described above. The data processing system 36 also includes a data processing component 40C that is configured to compute components of electrical load characteristics, such as those described above, from the frequency analyzed electrical power signals measured at the times t₁ and t₂. The data processing system 36 also includes a data processing component 40D that is configured to identify at least one change in operational state of at least one electrical appliance 18 based upon a difference in the components of the electrical load characteristics. Other features of the system 30C are similar to features of the system 30 (FIG. 2A) and need not be repeated for sake of brevity.

Referring now to FIG. 6B, the system 30C may include optional features, if desired, such as any one or more of those discussed with reference to FIG. 2B. For example, in some embodiments the data processing system 36 may also include a data processing component 40E that is configured to identify electrical appliances 18 based upon the difference in the components of the electrical load characteristics. In such an arrangement, the predetermined components of electrical load characteristics for predetermined electrical appliances may be stored in the data storage 46.

In some embodiments the data indicative of the at least one change in operational state of at least one electrical appliance 18 optionally may be stored in the data storage 48. Also, data indicative of identity of the identified appliances may be stored in the data storage 48 when the data processing system 36 includes the data processing component 40E. If desired, in some embodiments the data storage 48 may be removable.

Further, if desired the system 30C may include the communications system 50. When provided for the system 30C, the communications system 50 can be configured to communicate the data indicative of the at least one change in operational state of at least one electrical appliance 18 and/or, when the data processing system 36 includes the data processing component 40E, the data indicative of identity of the identified appliances.

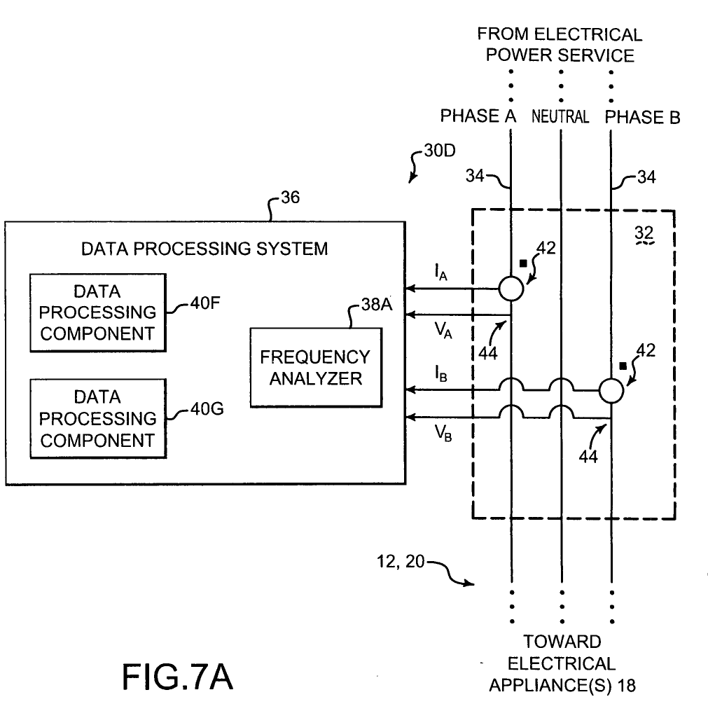

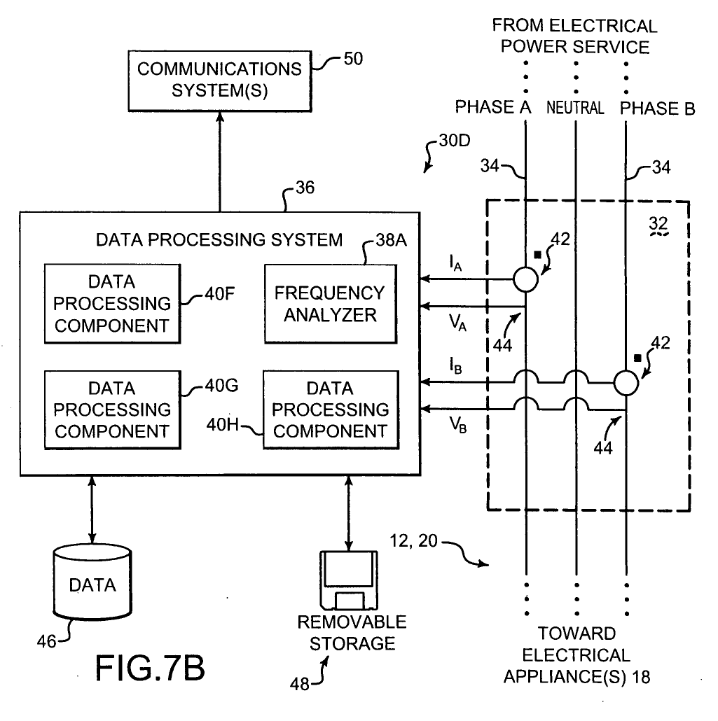

Referring now to FIG. 7A, a system 30D can identify at least one change in operational state of at least one of the electrical appliances 18. To that end, the data processing system 36 includes a data processing component 40F that is configured to compute electrical load characteristics from electrical power signals measured at the times t₁ and t₂. A frequency analyzer 38A is configured to frequency analyze the electrical load characteristics. A data processing component 40G is configured to identify at least one change in operational state of at least one electrical appliance 18 based upon a difference in components of the electrical load characteristics.

Referring now to FIG. 7B, the system 30D may include optional features, if desired, such as any one or more of those discussed with reference to FIG. 2B. For example, in some embodiments the data processing system 36 may also include a data processing component 40H that is configured to identify electrical appliances 18 based upon the difference in the components of the electrical load characteristics. In such an arrangement, the predetermined components of electrical load characteristics for predetermined electrical appliances may be stored in the data storage 46.

In some embodiments the data indicative of the at least one change in operational state of at least one electrical appliance 18 optionally may be stored in the data storage 48. Also, data indicative of identity of the identified appliances may be stored in the data storage 48 when the data processing system 36 includes the data processing component 40H. If desired, in some embodiments the data storage 48 may be removable.

Further, if desired the system 30 may include the communications system 50. When provided for the system 30D, the communications system 50 can be configured to communicate the data indicative of the at least one change in operational state of at least one electrical appliance 18 and/or, when the data processing system 36 includes the data processing component 40H, the data indicative of identity of the identified appliances.

It will be appreciated that any of the frequency analyzers 38 (FIGS. 4A, 4B, 5A, 5B, 6A, and 6B) and 38A (FIGS. 7A and 7B) and the data processing components 40 (FIGS. 4A and 4B), 40A and 40B (FIGS. 5A and 5B), 40C and 40D (FIGS. 6A and 6B), 40E (FIG. 6B), 40F and 40G (FIGS. 7A and 7B), and 40H (FIG. 7B) may be implemented within a processor or co-processor, as desired and as discussed above.

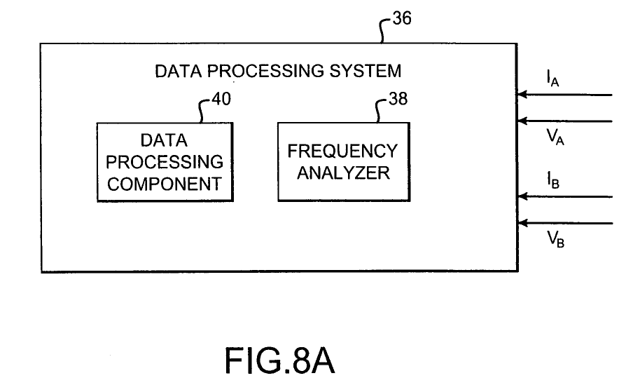

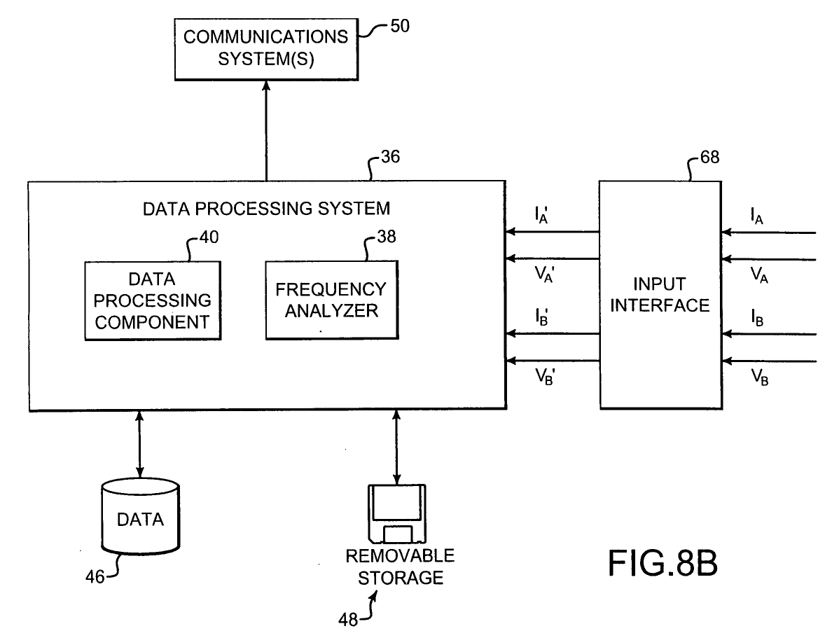

In some other embodiments, illustrative systems may be embodied as data processing systems. For example, referring now to FIG. 8A, the data processing system 36 can identify at least one change in operational state of at least one of the electrical appliances 18. To that end, the data processing system 36 includes the frequency analyzer 38 that frequency analyzes electrical signals that are indicative of the electrical power signals 34 measured at the times t₁ and t₂. The data processing system 36 also includes the data processing component 40 that can identify at least one change in operational state of at least one electrical appliance 18 based upon a difference in the frequency analyzed electrical signals.

In some embodiments the data processing system 36 receives the signals I_{A}, V_{A}, I_{B}, and V_{B} from a measurement device (not shown in FIG. 8A). The signals I_{A}, V_{A}, I_{B}, and V_{B} may be formatted, conditioned, and/or pre-processed as desired by the data processing system 36, as discussed above.

In some other embodiments and referring now to FIG. 8B, any desired formatting, conditioning, and/or pre-processing of the signals I_{A}, V_{A}, I_{B}, and V_{B} may be performed by an input interface 68. The input interface 68 receives the signals I_{A}, V_{A}, I_{B}, and V_{B} from a measurement device (not shown in FIG. 8B). When the signals I_{A}, V_{A}, I_{B}, and V_{B} are analog signals, in some embodiments if desired the input interface 68 can perform an analog-to-digital conversion of the signals I_{A}, V_{A}, I_{B}, and V_{B}. When the signals I_{A}, V_{A}, I_{B}, and V_{B} are digital signals, in some embodiments the input interface 68 may perform signal acquisition, handshaking, conditioning, and/or formatting processes as desired. After performing any desired formatting, conditioning, and/or pre-processing of the signals I_{A}, V_{A}, I_{B}, and V_{B}, the input interface 68 outputs signals I_{A}′, V_{A}′, I_{B}′, and V_{B}′ to the data processing system 36 for processing as described above.

Still referring to FIG. 8B, the data processing system 36 may interface with optional features, if desired, such as any one or more of those discussed with reference to FIG. 2B. For example, in some embodiments the data processing component 40 may be further configured to identify electrical appliances based upon the difference in the frequency analyzed electrical signals. In such an arrangement, the predetermined frequency analyzed electrical signals for predetermined electrical appliances may be stored in the data storage 46.

In some embodiments the data indicative of the at least one change in operational state of at least one electrical appliance optionally may be stored in the data storage 48. Also, data indicative of identity of the identified appliances may be stored in the data storage 48 when electrical appliances are identified. If desired, in some embodiments the data storage 48 may be removable.

Further, if desired the data processing system 36 may interface with the communications system 50. When provided, the communications system 50 can be configured to communicate the data indicative of the at least one change in operational state of at least one electrical appliance and/or, when electrical appliances are identified, the data indicative of identity of the identified appliances.

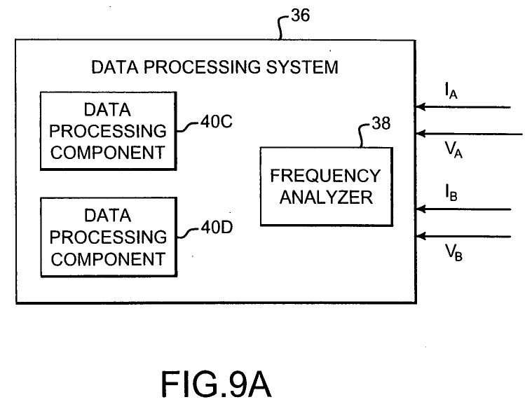

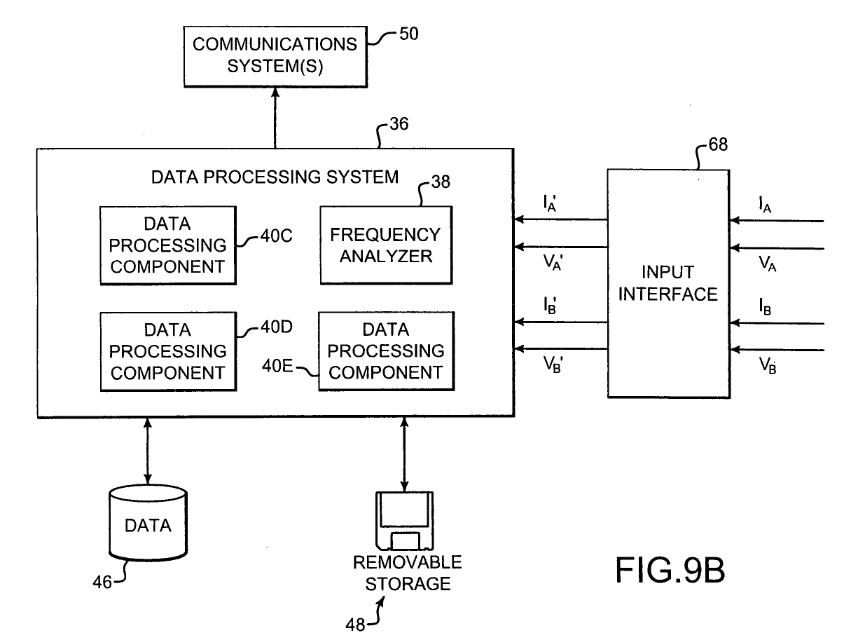

Referring now to FIG. 9A, another illustrative system may be embodied as a data processing system. For example, the data processing system 36 can identify at least one change in operational state of at least one of the electrical appliances 18. To that end, the data processing system 36 includes the frequency analyzer 38 that is configured to frequency analyze the measured electrical power signals as described above. The data processing system 36 also includes the data processing component 40C that is configured to compute components of electrical load characteristics, such as those described above, from the frequency analyzed electrical power signals measured at the times t₁ and t₂. The data processing system 36 also includes the data processing component 40D that is configured to identify at least one change in operational state of at least one electrical appliance 18 based upon a difference in the components of the electrical load characteristics.

In some embodiments the data processing system 36 receives the signals I_{A}, V_{A}, I_{B}, and V_{B} from a measurement device (not shown in FIG. 9A). The signals I_{A}, V_{A}, I_{B}, and V_{B} may be formatted, conditioned, and/or pre-processed as desired by the data processing system 36, as discussed above.

In some other embodiments and referring now to FIG. 9B, any desired formatting, conditioning, and/or pre-processing of the signals I_{A}, V_{A}, I_{B}, and V_{B} may be performed by the input interface 68, as discussed above.

Still referring to FIG. 9B, the data processing system 36 may interface with optional features, if desired, such as any one or more of those discussed with reference to FIG. 2B. For example, in some embodiments the data processing system 36 may also include the data processing component 40E that is configured to identify electrical appliances 18 based upon the difference in the components of the electrical load characteristics. In such an arrangement, the predetermined components of electrical load characteristics for predetermined electrical appliances may be stored in the data storage 46.

In some embodiments the data indicative of the at least one change in operational state of at least one electrical appliance optionally may be stored in the data storage 48. Also, data indicative of identity of the identified appliances may be stored in the data storage 48 when the data processing system 36 includes the data processing component 40E. If desired, in some embodiments the data storage 48 may be removable.

Further, if desired the data processing system 36 may interface with the communications system 50. When provided, the communications system 50 can be configured to communicate the data indicative of the at least one change in operational state of at least one electrical appliance and/or, when the data processing system 36 includes the data processing component 40E, the data indicative of identity of the identified appliances.

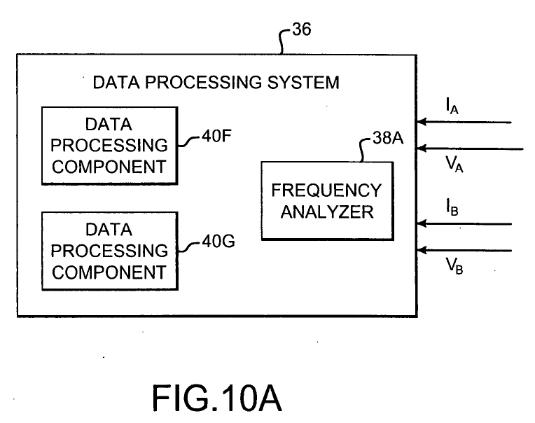

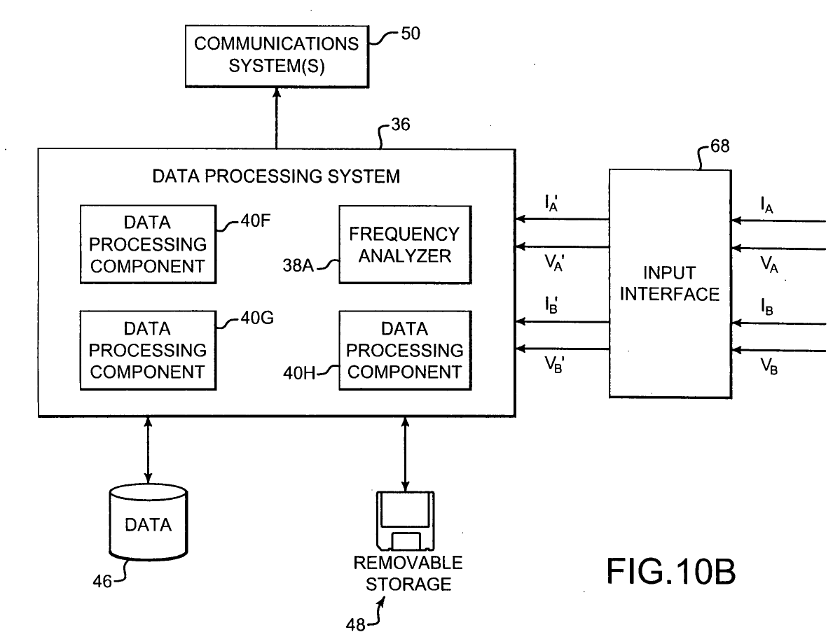

Referring now to FIG. 10A, another illustrative system may be embodied as a data processing system. For example, the data processing system 36 can identify at least one change in operational state of at least one of the electrical appliances 18. To that end, the data processing system 36 includes the data processing component 40F that is configured to compute electrical load characteristics from electrical power signals measured at the times t₁ and t₂. The frequency analyzer 38A is configured to frequency analyze the electrical load characteristics. The data processing component 40G is configured to identify at least one change in operational state of at least one electrical appliance 18 based upon a difference in components of the electrical load characteristics.

In some embodiments the data processing system 36 receives the signals I_{A}, V_{A}, I_{B}, and V_{B} from a measurement device (not shown in FIG. 10A). The signals I_{A}, V_{A}, I_{B}, and V_{B} may be formatted, conditioned, and/or pre-processed as desired by the data processing system 36, as discussed above.

In some other embodiments and referring now to FIG. 10B, any desired formatting, conditioning, and/or pre-processing of the signals I_{A}, V_{A}, I_{B}, and V_{B} may be performed by the input interface 68, as discussed above.

Still referring to FIG. 10B, the data processing system 36 may interface with optional features, if desired, such as any one or more of those discussed with reference to FIG. 2B. For example, in some embodiments the data processing system 36 may also include the data processing component 40E that is configured to identify electrical appliances 18 based upon the difference in the components of the electrical load characteristics. In such an arrangement, the predetermined components of electrical load characteristics for predetermined electrical appliances may be stored in the data storage 46.

In some embodiments the data indicative of the at least one change in operational state of at least one electrical appliance optionally may be stored in the data storage 48. Also, data indicative of identity of the identified appliances may be stored in the data storage 48 when the data processing system 36 includes the data processing component 40E. If desired, in some embodiments the data storage 48 may be removable.

Further, if desired the data processing system 36 may interface with the communications system 50. When provided, the communications system 50 can be configured to communicate the data indicative of the at least one change in operational state of at least one electrical appliance and/or, when the data processing system 36 includes the data processing component 40E, the data indicative of identity of the identified appliances.

Illustrative Methods

Now that illustrative embodiments of systems, including data processing systems, have been discussed, illustrative methods associated therewith will now be discussed.

Following are a series of flowcharts depicting implementations of processes. For ease of understanding, the flowcharts are organized such that the initial flowcharts present implementations via an overall “big picture” viewpoint and thereafter the following flowcharts present alternate implementations and/or expansions of the “big picture” flowcharts as either sub-steps or additional steps building on one or more earlier-presented flowcharts. Those having skill in the art will appreciate that the style of presentation utilized herein (e.g., beginning with a presentation of a flowchart(s) presenting an overall view and thereafter providing additions to and/or further details in subsequent flowcharts) generally allows for a rapid and easy understanding of the various process implementations. In addition, those skilled in the art will further appreciate that the style of presentation used herein also lends itself well to modular design paradigms.

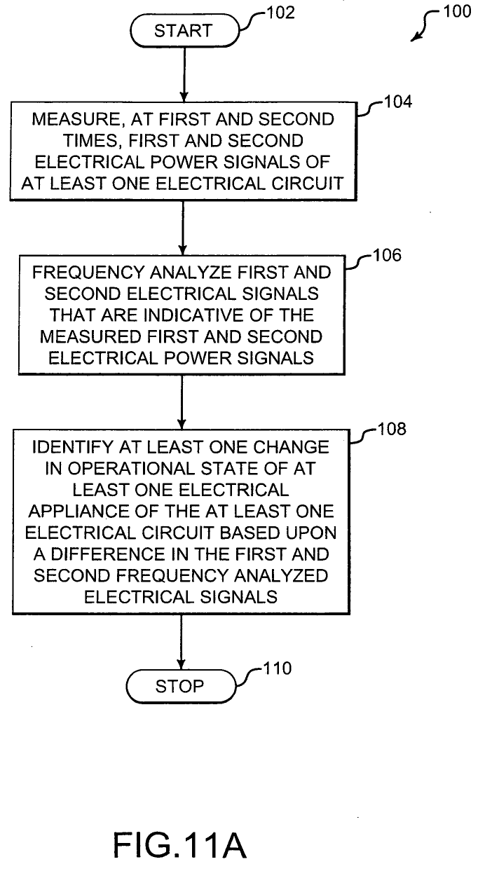

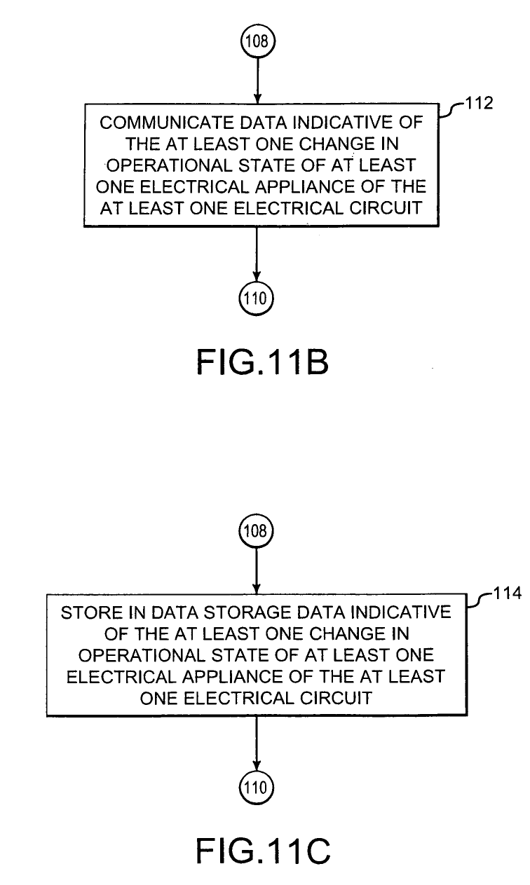

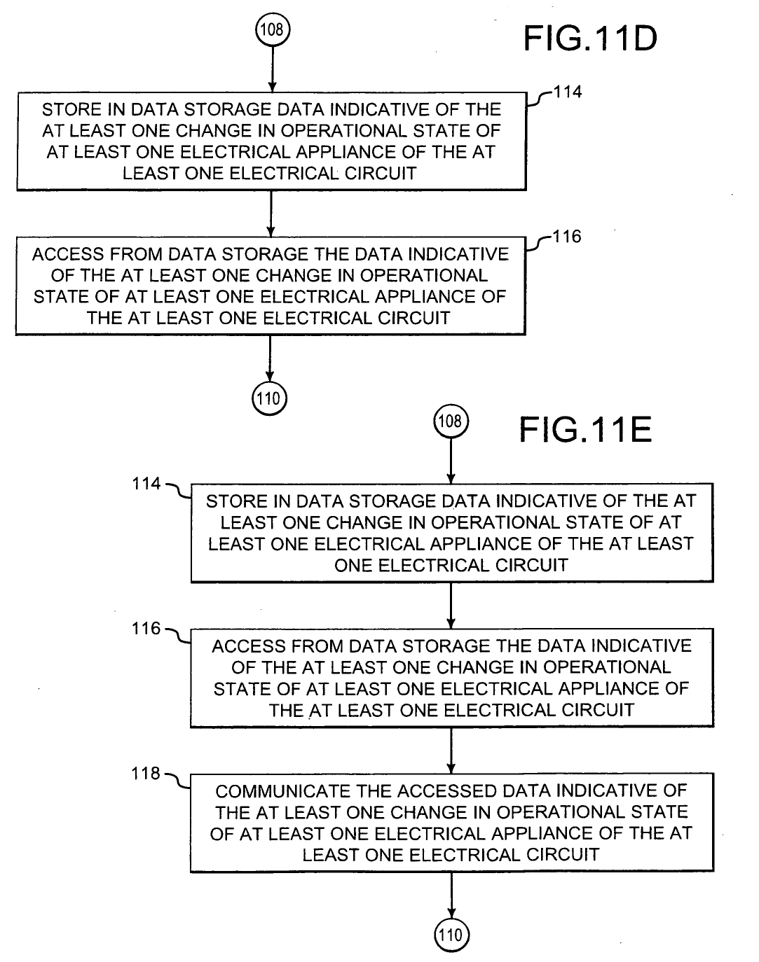

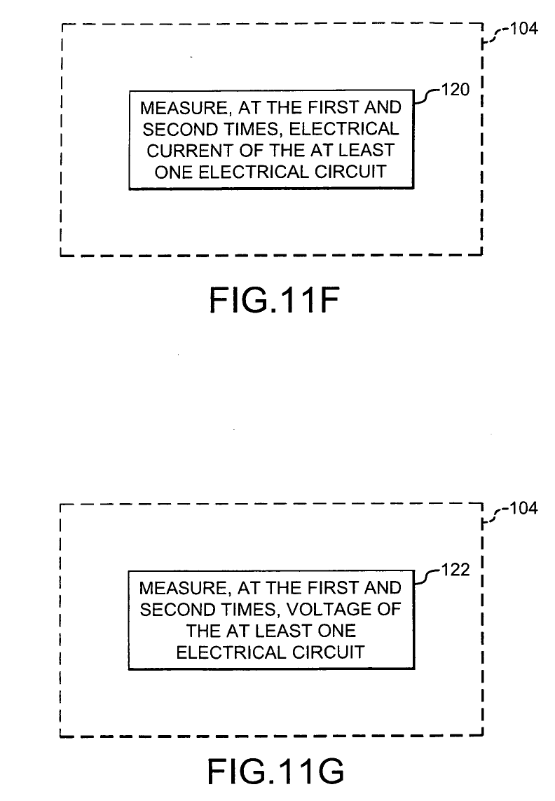

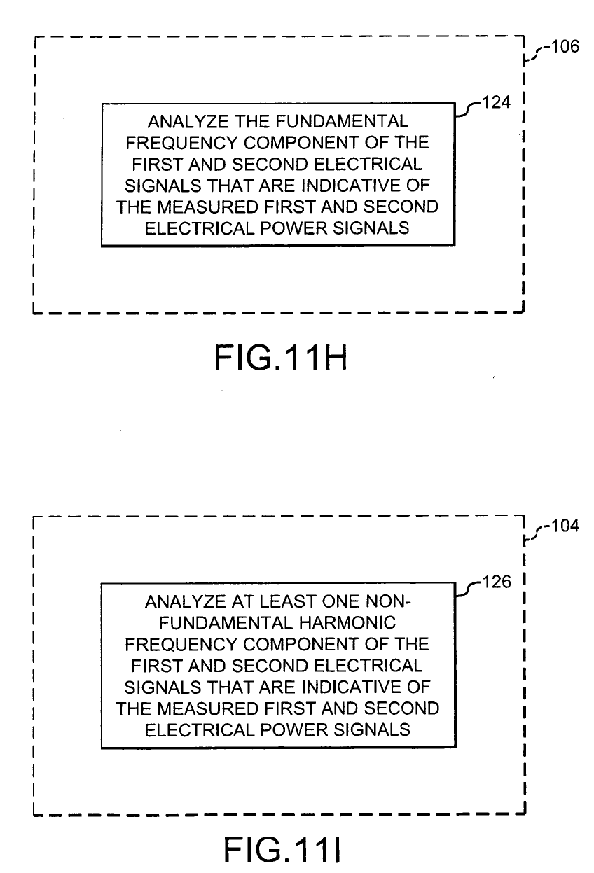

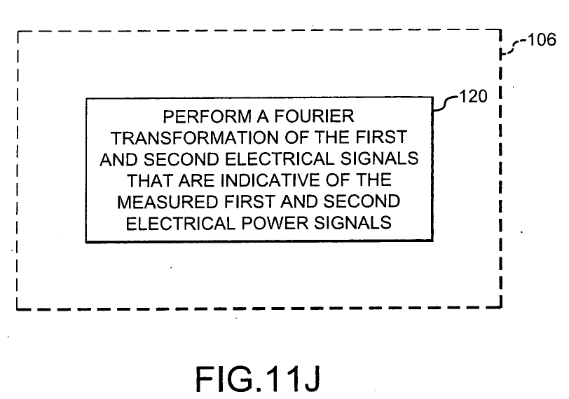

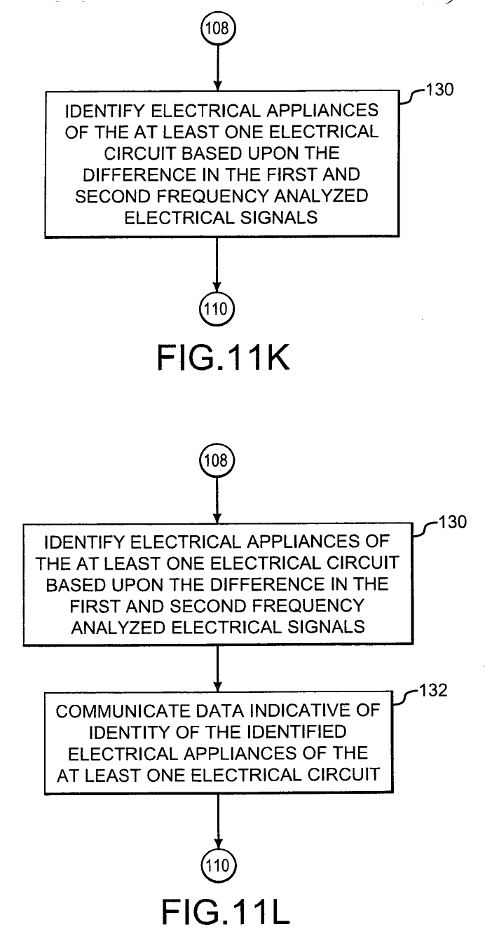

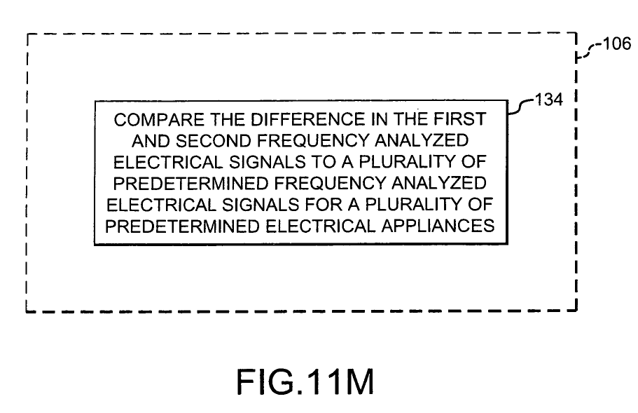

Referring now to FIG. 11A and by way of overview, an illustrative method 100 starts at a block 102. At a block 104 first and second electrical power signals of at least one electrical circuit are measured at first and second times. At a block 106 first and second electrical signals that are indicative of the measured first and second electrical power signals are frequency analyzed. At a block 108 at least one change in operational state of at least one electrical appliance of the at least one electrical circuit is identified based upon a difference in the first and second frequency analyzed electrical signals. The method 100 stops at a block 110. Some illustrative details will be explained below.

In some embodiments, operational state of at least one electrical appliance of the at least one electrical circuit can include a first operating state having a first set of electrical load characteristics and a second operating state having a second set of electrical load characteristics that are different from the first set of electrical load characteristics. In some embodiments, operational state of at least one electrical appliance of the at least one electrical circuit can include an on state and an off state.

Referring now to FIG. 11B, in some embodiments data indicative of the at least one change in operational state of at least one electrical appliance of the at least one electrical circuit may be communicated at a block 112. For example, the data indicative of the at least one change in operational state of at least one electrical appliance may be provided to a suitable communications system via a communications interface of a data processing system. In some embodiments, the communicating may be performed via power line carrier communication. In some embodiments, the communicating may be performed via wireless communication. In some other embodiments, the communicating may be performed via network communication.

Referring now to FIG. 11C, in some embodiments data indicative of the at least one change in operational state of at least one electrical appliance of the at least one electrical circuit may be stored in data storage at a block 114. In some embodiments the data storage may be removable. Referring now to FIG. 11D, in some embodiments the data indicative of the at least one change in operational state of at least one electrical appliance of the at least one electrical circuit may be accessed from data storage at a block 116. In some other embodiments and referring now to FIG. 11E, at a block 118 the accessed data indicative of the at least one change in operational state of at least one electrical appliance of the at least one electrical circuit may be communicated.

Referring now to FIG. 11F, measuring, at first and second times, first and second electrical power signals of at least one electrical circuit at the block 104 may include measuring, at the first and second times, electrical current of the at least one electrical circuit at a block 120. For example, a measuring system can, at any desired location of at least one electrical circuit, measure at times t₁ and t₂ electrical current of phases A and B of at least one electrical circuit with a suitable current measurement device, such as without limitation a current transformer or an ammeter such as a non-contact ammeter like an ammeter clamp or the like, and provide electrical signals I_{A} and I_{B}.

Referring now FIG. 11G, measuring, at first and second times, first and second electrical power signals of at least one electrical circuit at the block 104 may include measuring, at the first and second times, voltage of the at least one electrical circuit at a block 122. For example, a measuring system can, at ally desired location of at least one electrical circuit, measure at times t₁ and t₂ voltage of phase A with respect to neutral and voltage of phase B with respect to neutral of at least one electrical circuit with a suitable voltage measurement device such as a test lead or probe like a non-contact voltage probe or the like and provide electrical signals V_{A} and V_{B}.

As discussed above, the measuring at the blocks 120 (FIG. 11F) and 122 (FIG. 11G) can be performed at any location as desired. For example and without limitation, the first and second electrical power signals can be measured at a location within the electrical circuit, at a location that is electrically proximate to an isolation point of the electrical circuit, at an electrical service entrance that supplies the at least one electrical circuit, or at a power line between an electric utility and an electrical service entrance that supplies the at least one electrical circuit.

Referring back to FIG. 11A, in some embodiments the first and second electrical signals that are indicative of the measured first and second electrical power signals (that are frequency analyzed at the block 106) can include the measured first and second electrical power signals, such as electrical current of the at least one electrical circuit (FIG. 11F) and/or voltage of the at least one electrical circuit (FIG. 11G).

In some other embodiments, the first and second electrical signals that are indicative of the measured first and second electrical power signals (that are frequency analyzed at the block 106) can include first and second calculated parameter signals. The calculated parameter can be an electrical load characteristic. In some embodiments, the calculated parameter can include real power and/or reactive power. In some other embodiments, the calculated parameter can include conductance and/or susceptance.

Referring now to FIG. 11H, in some embodiments frequency analyzing first and second electrical signals that are indicative of the measured first and second electrical power signals at the block 106 can include analyzing the fundamental frequency component of the first and second electrical signals that are indicative of the measured first and second electrical power signals at a block 124.

Referring now to FIG. 11I, in some other embodiments frequency analyzing first and second electrical signals that are indicative of the measured first and second electrical power signals at the block 106 can include analyzing at least one non-fundamental harmonic frequency component of the first and second electrical signals that are indicative of the measured first and second electrical power signals at a block 126. As discussed above, in some embodiments the at least one non-fundamental harmonic frequency component can include at least one odd non-fundamental harmonic frequency component, such as without limitation a third harmonic frequency component.

Referring now to FIG. 11J, in some embodiments frequency analyzing first and second electrical signals that are indicative of the measured first and second electrical power signals at the block 106 can include performing a Fourier transformation of the first and second electrical signals that are indicative of the measured first and second electrical power signals at a block 128.

Referring now to FIG. 11K, in some embodiments electrical appliances of the at least one electrical circuit can be identified based upon the difference in the first and second frequency analyzed electrical signals at a block 130.

Referring now to FIG. 11L, in some embodiments data indicative of identity of the identified electrical appliances of the at least one electrical circuit can be communicated. Communication at the block 130 can be performed similar to communication at the block 112 (FIG. 11B).

Referring now to FIG. 11M, in some embodiments identifying electrical appliances of the at least one electrical circuit based upon the difference in the first and second frequency analyzed electrical signals at the block 130 can include comparing the difference in the first and second frequency analyzed electrical signals to a plurality of predetermined frequency analyzed electrical signals for a plurality of predetermined electrical appliances at a block 134.

Now that the method 100 has been explained, other methods will be explained by way of illustration and not of limitation.

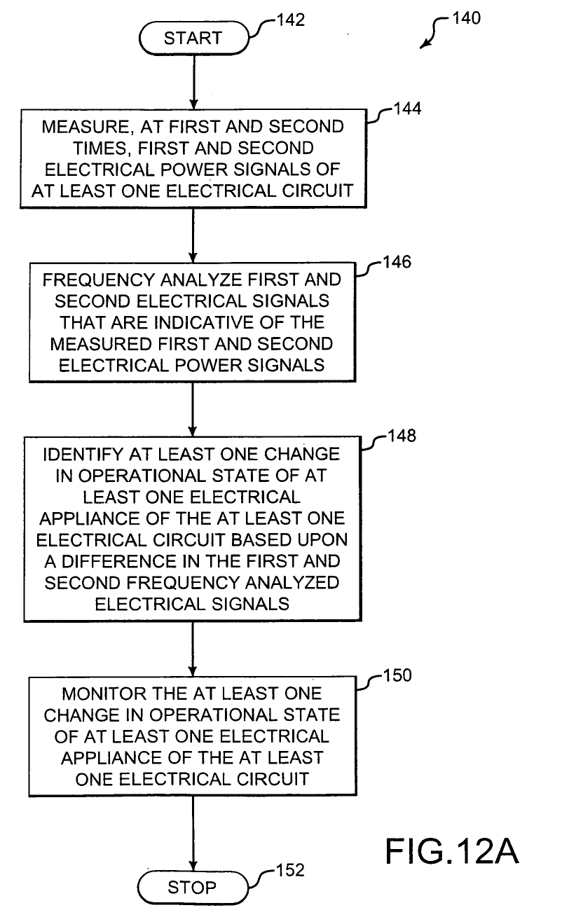

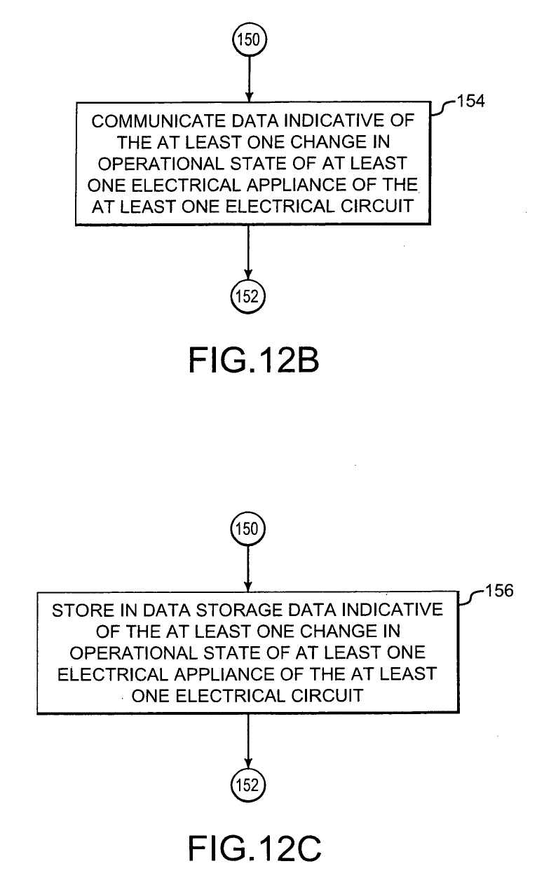

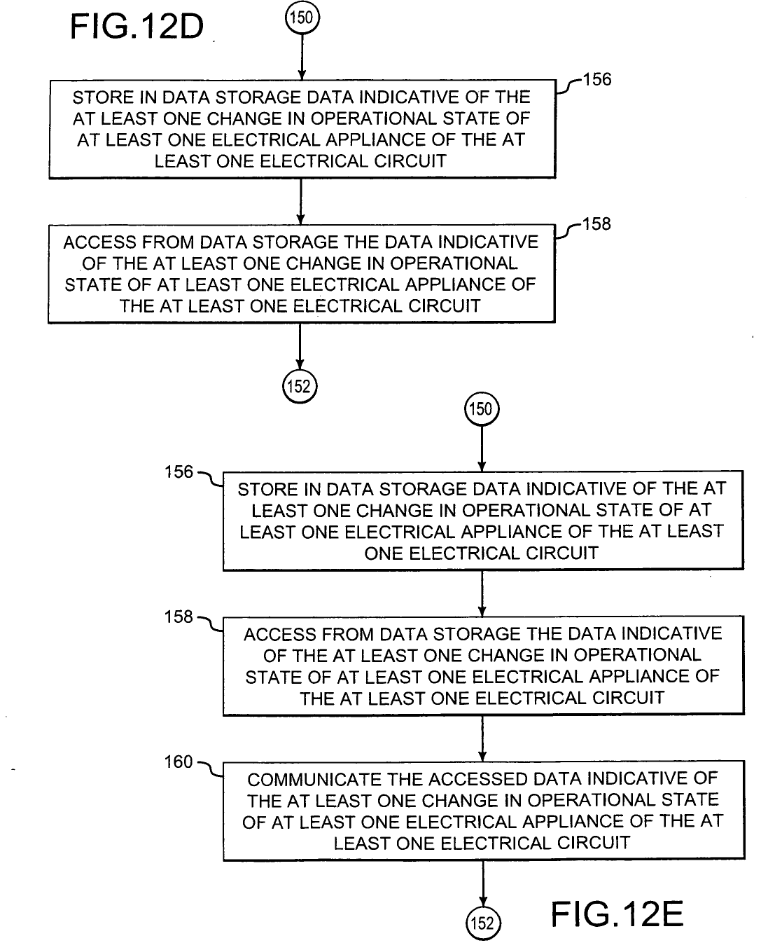

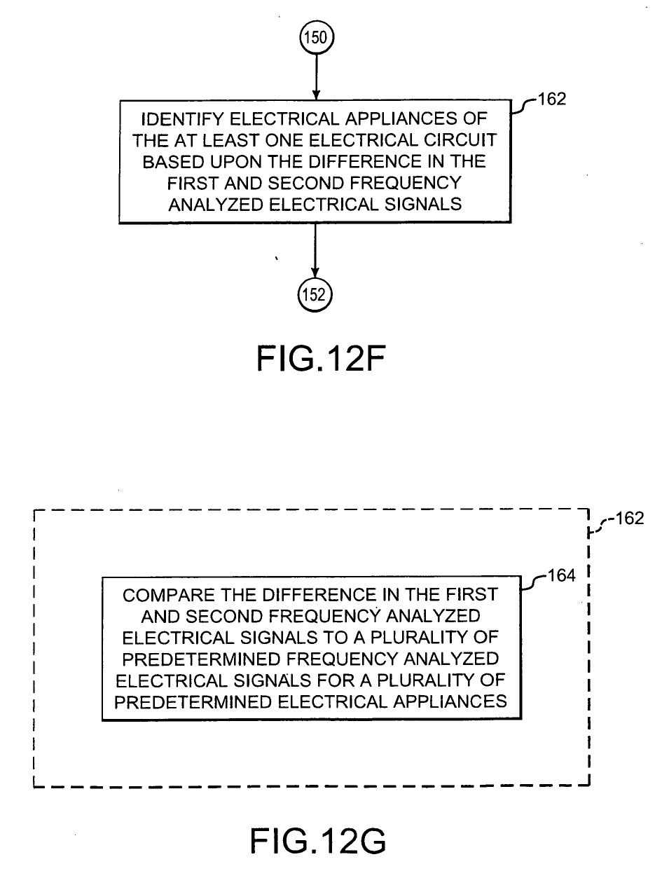

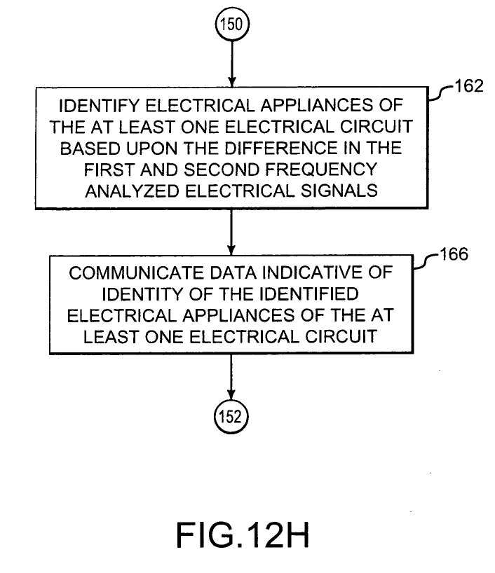

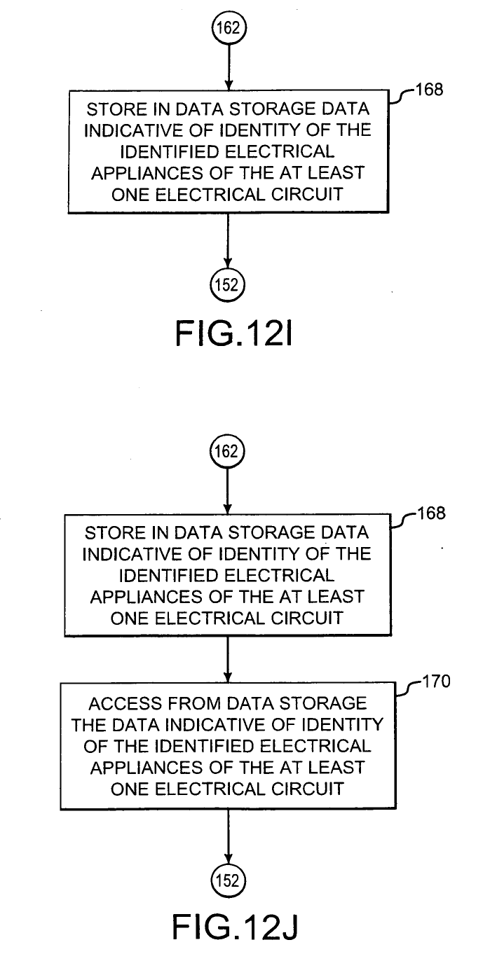

Referring now to FIG. 12A and by way of overview, a method 140 can monitor electrical appliances. The method 140 starts at a block 142. At a block 144 first and second electrical power signals of at least one electrical circuit are measured at first and second times. At a block 146 first and second electrical signals that are indicative of the measured first and second electrical power signals are frequency analyzed. At a block 148 at least one change in operational state of at least one electrical appliance of the at least one electrical circuit is identified based upon a difference in the first and second frequency analyzed electrical signals. At a block 150 the at least one change in operational state of at least one electrical appliance of the at least one electrical circuit is monitored. The method 140 stops at a block 152. Some illustrative details will be explained below.

Referring now to FIG. 12B, at a block 154 data indicative of the at least one change in operational state of at least one electrical appliance of the at least one electrical circuit may be communicated. Processing at the block 154 may be similar to that of the block 112 (FIG. 11B), discussed above.

Referring now to FIG. 12C, at a block 156 data indicative of the at least one change in operational state of at least one electrical appliance of the at least one electrical circuit may be stored in data storage. Processing at the block 156 may be similar to that of the block 114 (FIG. 11C), discussed above.

Referring now to FIG. 12D, at a block 158 the data indicative of the at least one change in operational state of at least one electrical appliance of the at least one electrical circuit may be accessed from data storage. Processing at the block 158 may be similar to that of the block 116 (FIG. 11D), discussed above.

Referring now to FIG. 12E, at a block 160 the accessed data indicative of the at least one change in operational state of at least one electrical appliance of the at least one electrical circuit may be communicated. Processing at the block 160 may be similar to that of the block 118 (FIG. 11E), discussed above.

Referring now to FIG. 12F, at a block 162 electrical appliances of the at least one electrical circuit based upon the difference in the first and second frequency analyzed electrical signals may be identified. Processing at the block 162 may be similar to that of the block 130 (FIG. 11K), discussed above.

Referring now to FIG. 12G, identifying electrical appliances of the at least one electrical circuit based upon the difference in the first and second frequency analyzed electrical signals at the block 162 can include comparing the difference in the first and second frequency analyzed electrical signals to a plurality of predetermined frequency analyzed electrical signals for a plurality of predetermined electrical appliances at a block 164. Processing at the block 164 may be similar to that of the block 134 (FIG. 11M), discussed above.

Referring now to FIG. 12H, at a block 166 data indicative of identity of the identified electrical appliances of the at least one electrical circuit may be communicated. Processing at the block 166 may be similar to that of the block 132 (FIG. 11L), discussed above.

Referring now to FIG. 12I, at a block 168 data indicative of identity of the identified electrical appliances of the at least one electrical circuit may be stored in data storage. Processing at the block 168 to store the data indicative of identity of the identified electrical appliances may be similar to that of the block 114 (FIG. 11C) to store the data indicative of the at least one change in operational state of at least one electrical appliance, discussed above.

Referring now to FIG. 12J, at a block 170 the data indicative of identity of the identified electrical appliances of the at least one electrical circuit may be accessed from data storage. Processing at the block 170 to access from data storage the data indicative of identity of the identified electrical appliances may be similar to that of the block 116 (FIG. 11D) to access from data storage the data indicative of the at least one change in operational state of at least one electrical appliance, discussed above.

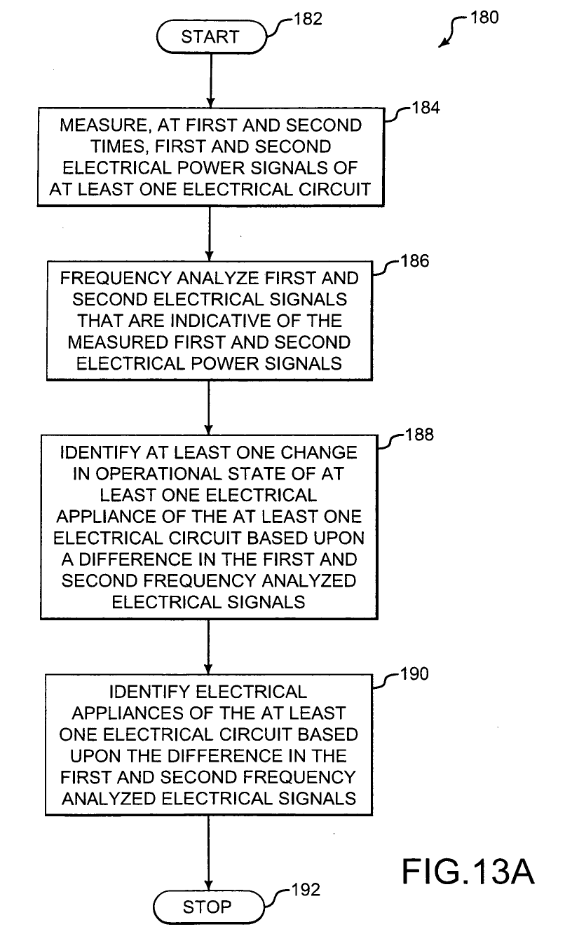

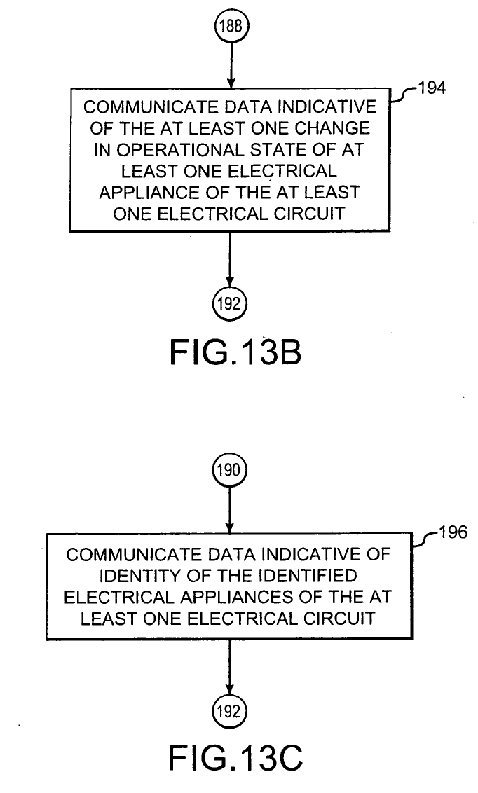

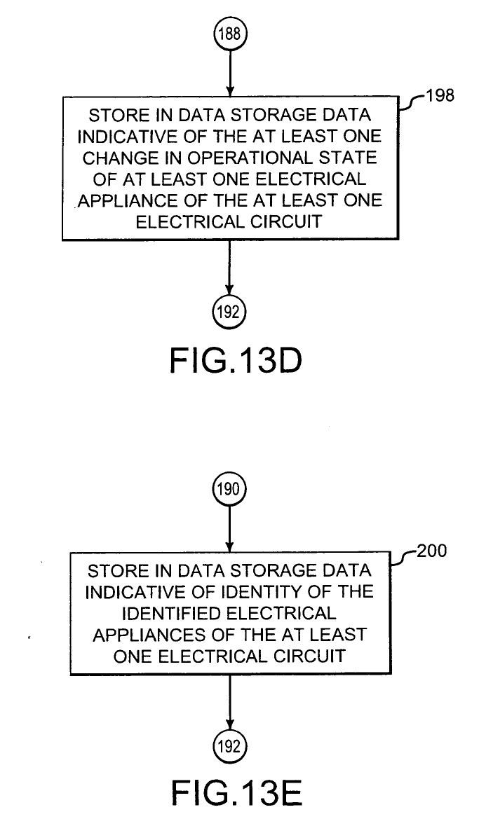

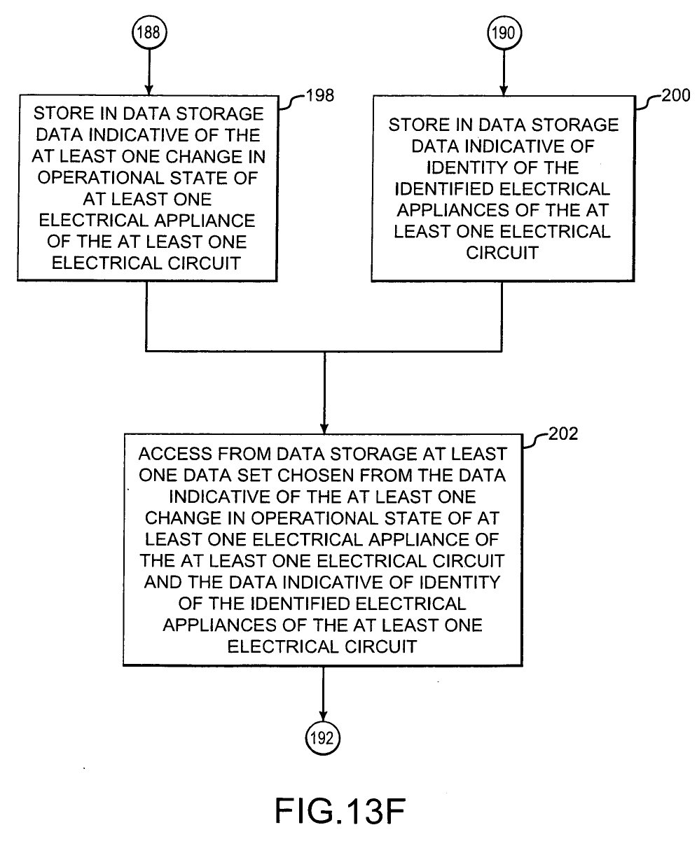

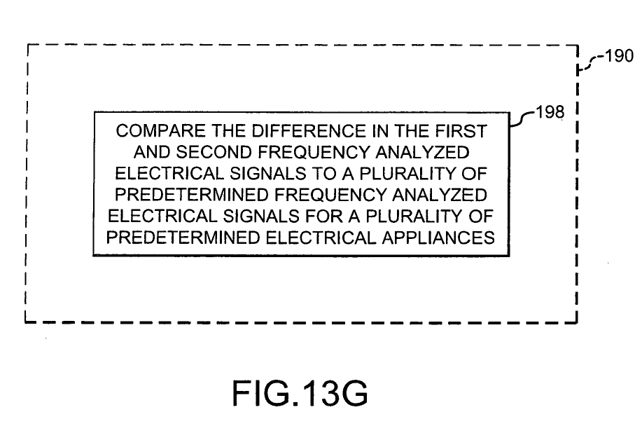

Referring now to FIG. 13A, and by way of overview, a method 180 starts at a block 182. At a block 184 first and second electrical power signals of at least one electrical circuit are measured at first and second times. At a block 186 first and second electrical signals that are indicative of the measured first and second electrical power signals are frequency analyzed. At a block 188 at least one change in operational state of at least one electrical appliance of the at least one electrical circuit is identified based upon a difference in the first and second frequency analyzed electrical signals. At a block 190 electrical appliances of the at least one electrical circuit can be identified based upon the difference in the first and second frequency analyzed electrical signals. The method 180 stops at a block 192. Some illustrative details will be explained below.

Referring now to FIG. 13B, at a block 194 data indicative of the at least one change in operational state of at least one electrical appliance of the at least one electrical circuit may be communicated. Processing at the block 194 may be similar to that of the block 112 (FIG. 11B), discussed above.

Referring now to FIG. 13C, at a block 196 data indicative of identity of the identified electrical appliances of the at least one electrical circuit may be communicated. Processing at the block 196 may be similar to that of the block 132 (FIG. 11L), discussed above.

Referring now to FIG. 13D, at a block 198 data indicative of the at least one change in operational state of at least one electrical appliance of the at least one electrical circuit may be stored in data storage. Processing at the block 198 may be similar to that of the block 114 (FIG. 11C), discussed above.

Referring now to FIG. 13E, at a block 200 data indicative of identity of the identified electrical appliances of the at least one electrical circuit may be stored in data storage. Processing at the block 200 to store the data indicative of identity of the identified electrical appliances may be similar to that of the block 114 (FIG. 11C) to store the data indicative of the at least one change in operational state of at least one electrical appliance, discussed above.

Referring now to FIG. 13F, at a block 202 the data indicative of the at least one change in operational state of at least one electrical appliance of the at least one electrical and/or the data indicative of identity of the identified electrical appliances of the at least one electrical circuit may be accessed from data storage. Processing at the block 202 may be similar to that of the blocks 116 (FIG. 11D) and/or 170 (FIG. 12J).

Referring now to FIG. 13G, identifying electrical appliances of the at least one electrical circuit based upon the difference in the first and second frequency analyzed electrical signals at the block 190 can include comparing the difference in the first and second frequency analyzed electrical signals to a plurality of predetermined frequency analyzed electrical signals for a plurality of predetermined electrical appliances at a block 204. Processing at the block 204 may be similar to that of the block 134 (FIG. 11M), discussed above.

It will be appreciated that in various method embodiments frequency analysis can be performed on different electrical signals in different relative stages of the method embodiment. For example, in some embodiments frequency analysis can be performed on measured electrical signals before calculated parameters, such as electrical load characteristics, are computed. As another example, in some other embodiments calculated parameters, such as electrical load characteristics, are computed and then frequency analysis is performed on the calculated parameters. Illustrative methods that highlight this aspect will now be explained below.

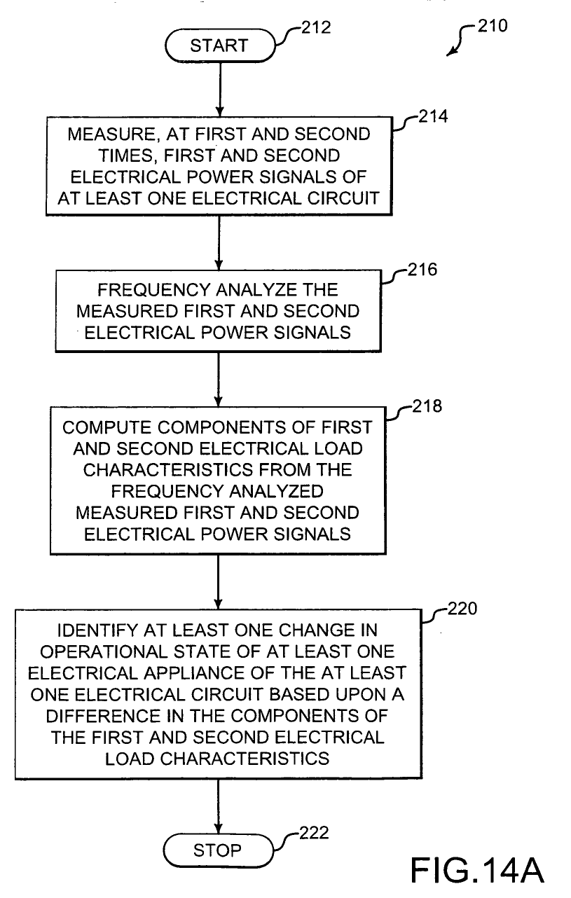

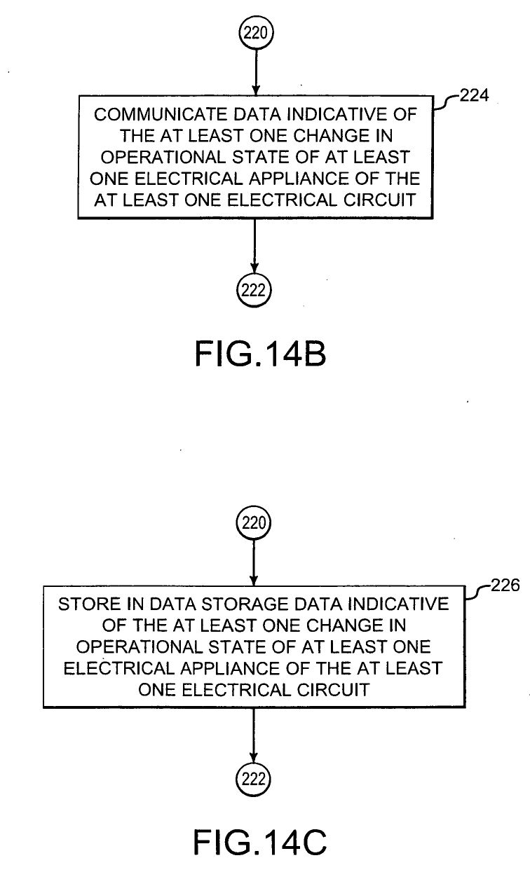

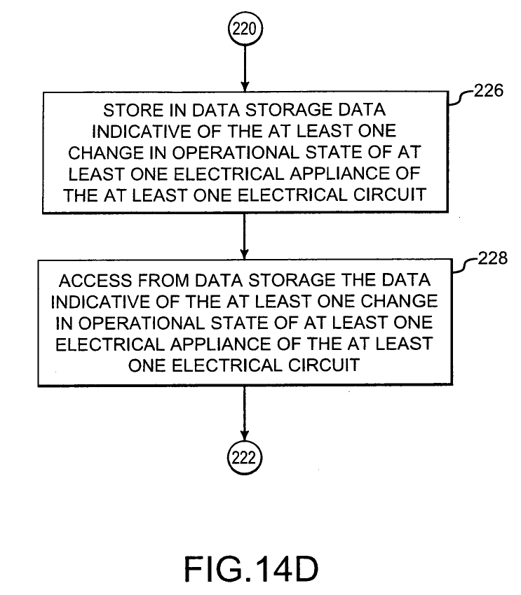

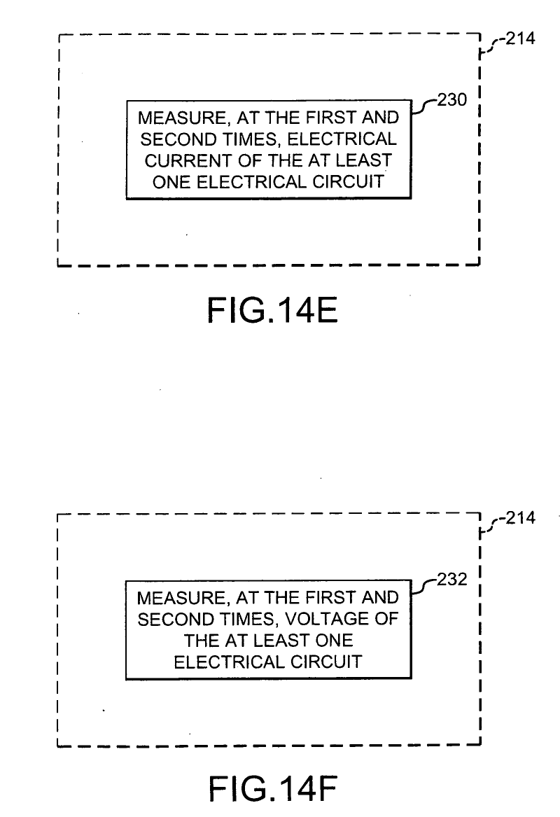

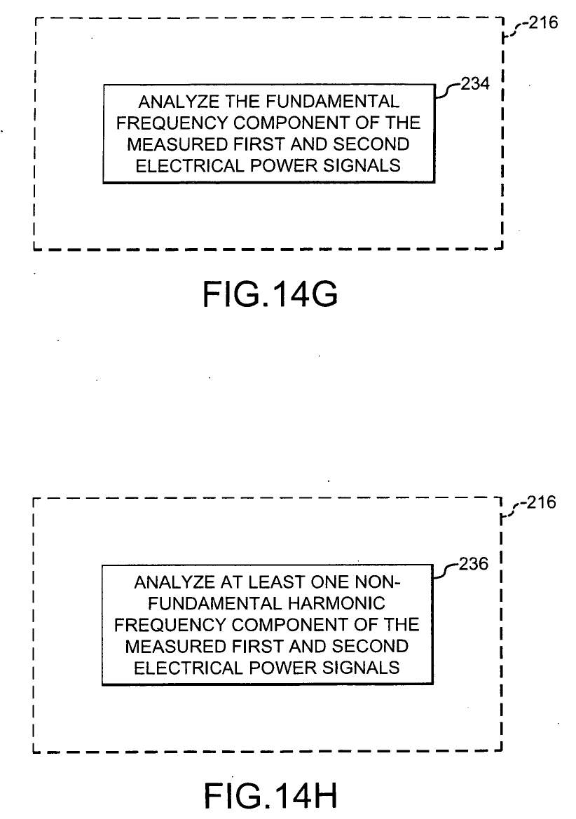

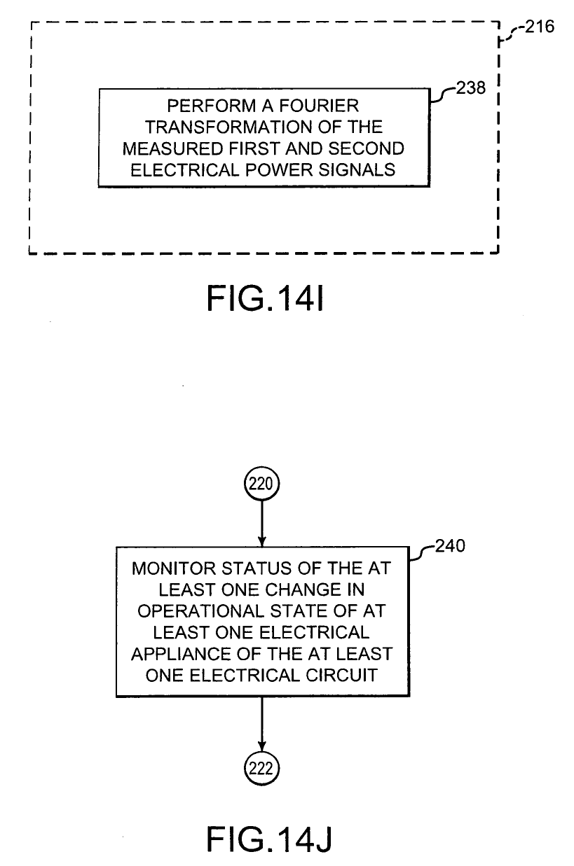

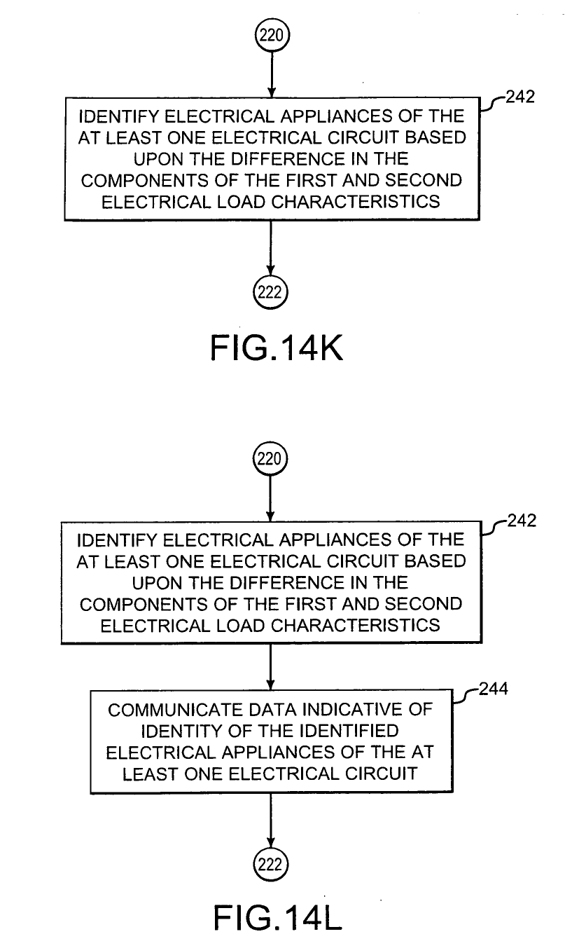

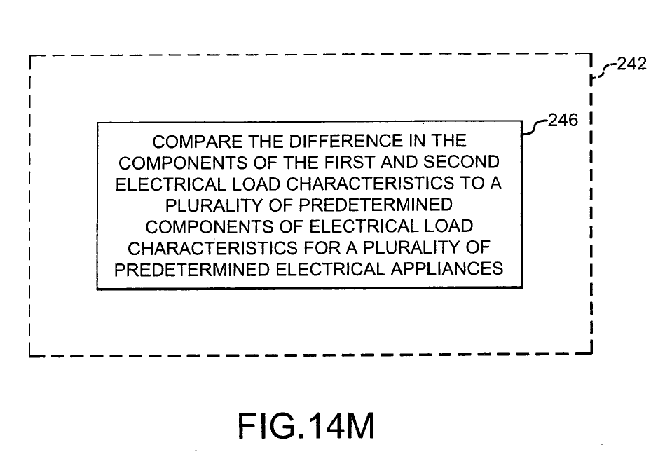

Referring now to FIG. 14A and by way of overview, a method 210 starts at a block 212. At a block 214 first and second electrical power signals of at least one electrical circuit are measured at first and second times. At a block 216 the measured first and second electrical power signals are frequency analyzed. At a block 218 components of first and second electrical load characteristics are computed from the frequency analyzed measured first and second electrical power signals, respectively. At a block 220 at least one change in operational state of at least one electrical appliance of the at least one electrical circuit are identified based upon a difference in the components of the first and second electrical load characteristics. The method 210 stops at a block 222. Some illustrative details will be explained below.

Referring now to FIG. 14B, at a block 224 data indicative of the at least one change in operational state of at least one electrical appliance of the at least one electrical circuit may be communicated. Processing at the block 224 may be similar to that of the block 112 (FIG. 11B), discussed above.

Referring now to FIG. 14C, at a block 226 data indicative of the at least one change in operational state of at least one electrical appliance of the at least one electrical circuit may be stored in data storage. Processing at the block 226 may be similar to that of the block 114 (FIG. 11C), discussed above.

Referring now to FIG. 14D, at a block 228 the data indicative of the at least one change in operational state of at least one electrical appliance of the at least one electrical circuit may be accessed from data storage. Processing at the block 228 may be similar to that of the block 116 (FIG. 11D), discussed above.

Referring now to FIG. 14E, measuring, at first and second times, first and second electrical power signals of at least one electrical circuit at the block 214 may include measuring, at the first and second times, electrical current of the at least one electrical circuit at a block 230. Processing at the block 230 may be similar to that of the block 120 (FIG. 11F), discussed above.

Referring now FIG. 14F, measuring, at first and second times, first and second electrical power signals of at least one electrical circuit at the block 214 may include measuring, at the first and second times, voltage of the at least one electrical circuit at a block 232. Processing at the block 232 may be similar to that of the block 122 (FIG. 11G), discussed above.

Referring now to FIG. 14G, frequency analyzing the measured first and second electrical power signals at the block 216 can include analyzing the fundamental frequency component of the measured first and second electrical power signals at a block 234. Processing at the block 234 may be similar to that of the block 124 (FIG. 11H), discussed above.

Referring now to FIG. 14H, frequency analyzing the measured first and second electrical power signals at the block 216 can include analyzing at least one non-fundamental harmonic frequency component of the measured first and second electrical power signals at a block 236. Processing at the block 236 may be similar to that of the block 126 (FIG. 11I), discussed above.

Referring now to FIG. 14I, frequency analyzing the measured first and second electrical power signals at the block 216 can include performing a Fourier transformation of the measured first and second electrical power signals at a block 238. Processing at the block 238 may be similar to that of the block 128 (FIG. 11J), discussed above.

Referring now to FIG. 14J, in some embodiments status of the at least one change in operational state of at least one electrical appliance of the at least one electrical circuit can be monitored at a block 240. Processing at the block 240 may be similar to that of the block 150 (FIG. 12A), discussed above.

Referring now to FIG. 14K, in some embodiments electrical appliances of the at least one electrical circuit can be identified based upon the difference in the components of the first and second electrical load characteristics at a block 242. Processing at the block 242 may be similar to that of the block 130 (FIG. 11K), discussed above.

Referring now to FIG. 14L, data indicative of identity of the identified electrical appliances of the at least one electrical circuit may be communicated at a block 244. Processing at the block 244 may be similar to that of the block 132 (FIG. 11L), discussed above.

Referring now to FIG. 14M, identifying electrical appliances of the at least one electrical circuit based upon the difference in the components of the first and second electrical load characteristics at the block 242 can include comparing the difference in the components of the first and second electrical load characteristics to a plurality of predetermined components of electrical load characteristics for a plurality of predetermined electrical appliances at a block 246. Processing at the block 246 may be similar to that of the block 134 (FIG. 11M), discussed above.

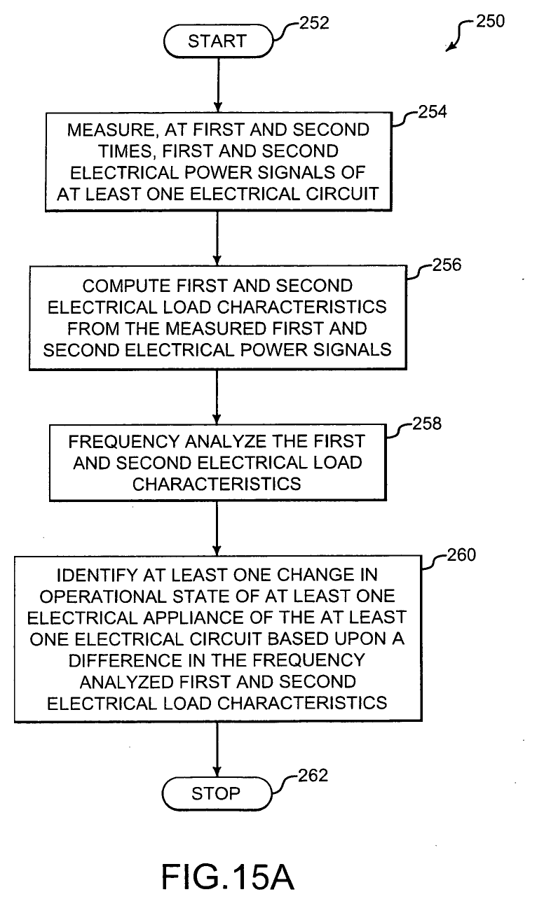

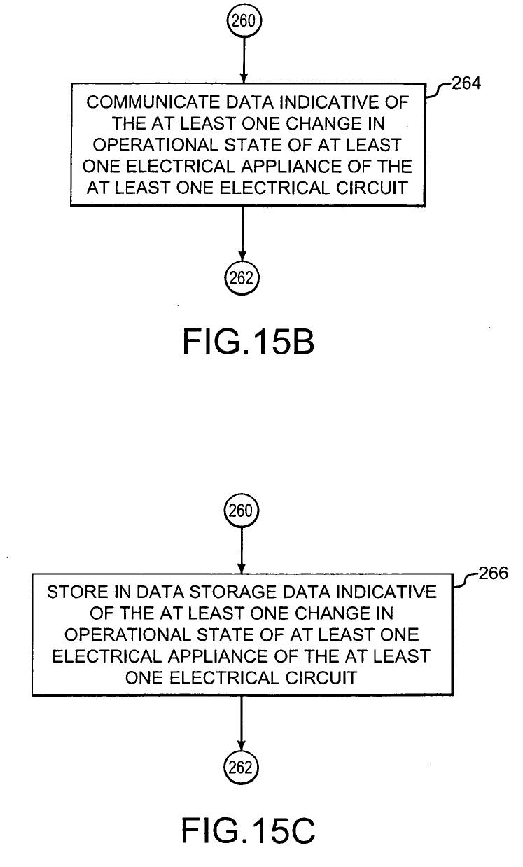

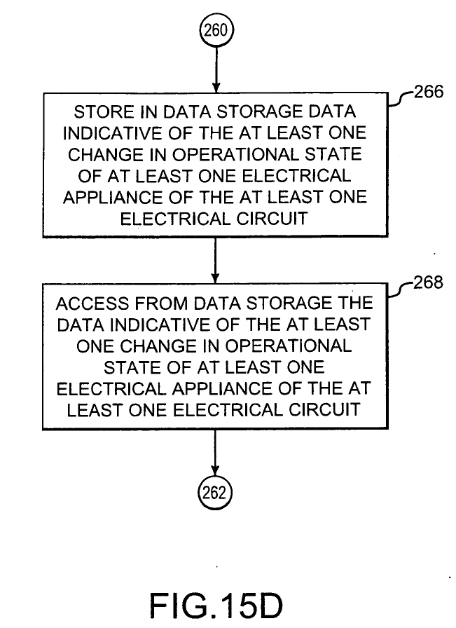

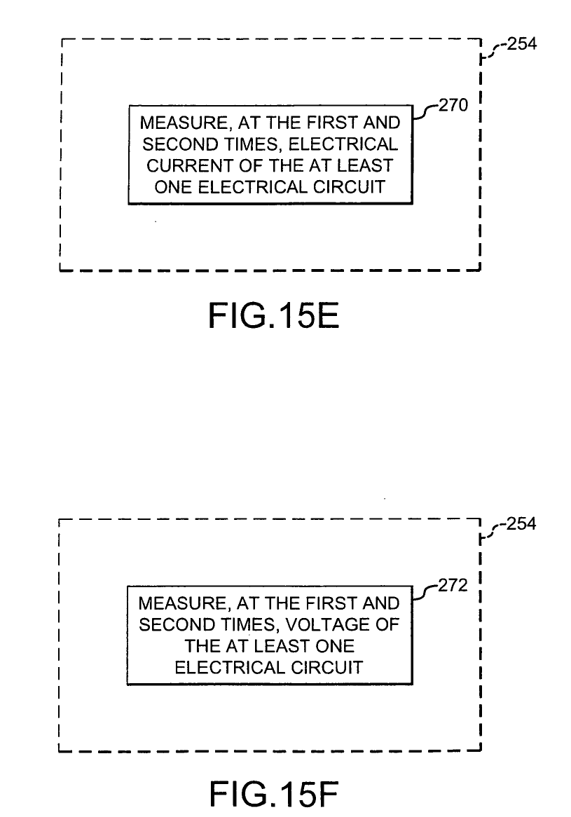

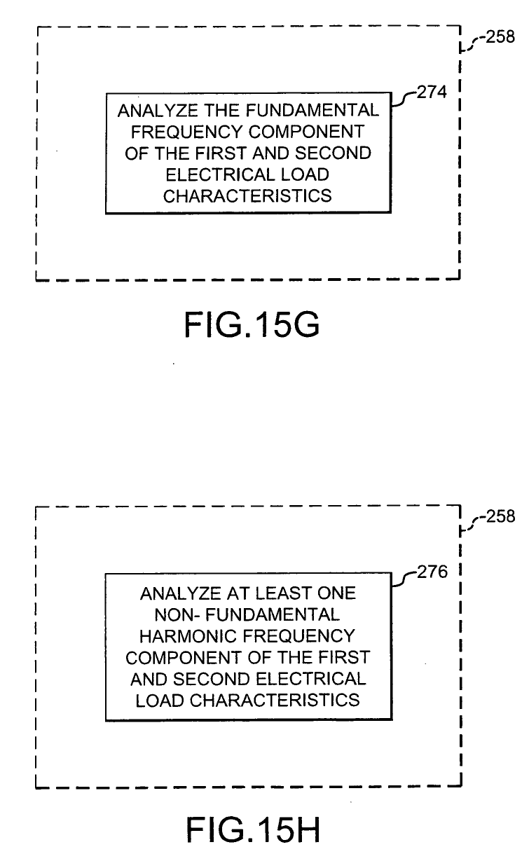

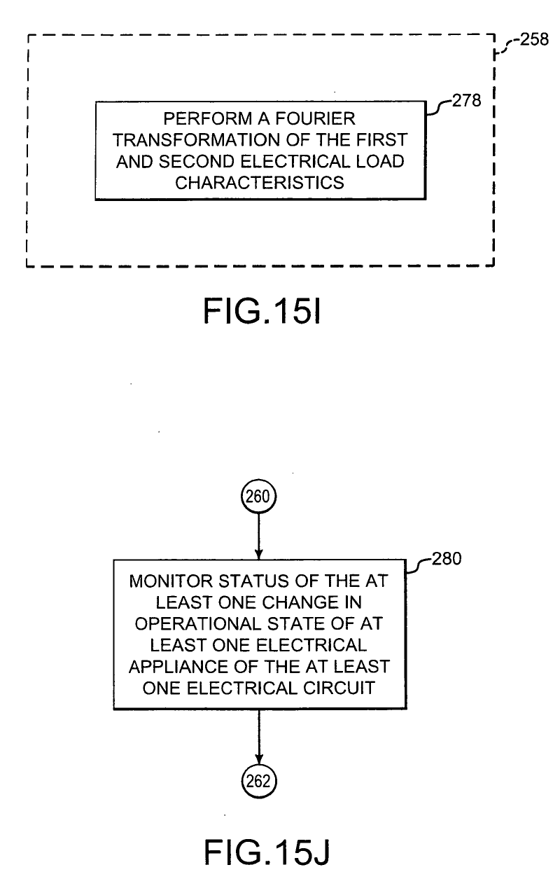

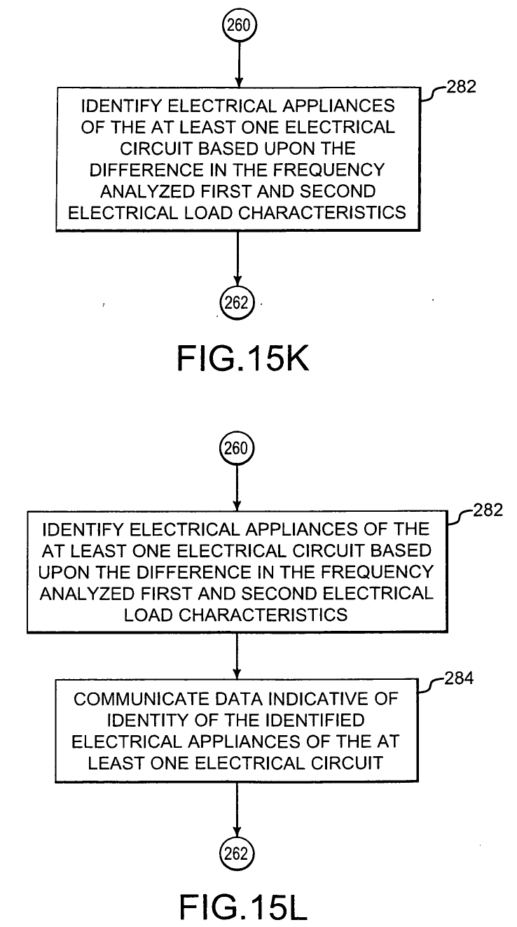

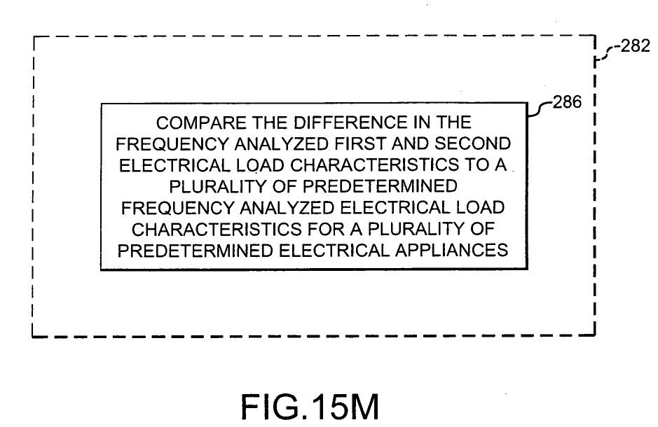

Referring now to FIG. 15A and by way of overview, a method 250 starts at a block 252. At a block 254 first and second electrical power signals of at least one electrical circuit are measured at first and second times. At a block 256 first and second electrical load characteristics are computed from the measured first and second electrical power signals, respectively. At a block 258 the first and second electrical load characteristics are frequency analyzed. At a block 260 at least one change in operational state of at least one electrical appliance of the at least one electrical circuit are identified based upon a difference in the frequency analyzed first and second electrical load characteristics. The method 250 stops at a block 262. Some illustrative details will be explained below.

Referring now to FIG. 15B, at a block 264 data indicative of the at least one change in operational state of at least one electrical appliance of the at least one electrical circuit may be communicated. Processing at the block 264 may be similar to that of the block 112 (FIG. 11B), discussed above.

Referring now to FIG. 15C, at a block 266 data indicative of the at least one change in operational state of at least one electrical appliance of the at least one electrical circuit may be stored in data storage. Processing at the block 266 may be similar to that of the block 114 (FIG. 11C), discussed above.

Referring now to FIG. 15D, at a block 268 the data indicative of the at least one change in operational state of at least one electrical appliance of the at least one electrical circuit may be accessed from data storage. Processing at the block 268 may be similar to that of the block 116 (FIG. 11D), discussed above.

Referring now to FIG. 15E, measuring, at first and second times, first and second electrical power signals of at least one electrical circuit at the block 254 may include measuring, at the first and second times, electrical current of the at least one electrical circuit at a block 270. Processing at the block 270 may be similar to that of the block 120 (FIG. 11F), discussed above.

Referring now FIG. 15F, measuring, at first and second times, first and second electrical power signals of at least one electrical circuit at the block 254 may include measuring, at the first and second times, voltage of the at least one electrical circuit at a block 272. Processing at the block 272 may be similar to that of the block 122 (FIG. 11G), discussed above.

Referring now to FIG. 15G, frequency analyzing the first and second electrical load characteristics at the block 258 can include analyzing the fundamental frequency component of the first and second electrical load characteristics at a block 274. Processing at the block 274 may be similar to that of the block 124 (FIG. 11H), discussed above.

Referring now to FIG. 15H, frequency analyzing the first and second electrical load characteristics at the block 258 can include analyzing at least one non-fundamental harmonic frequency component of the first and second electrical load characteristics at a block 276. Processing at the block 276 may be similar to that of the block 126 (FIG. 11I), discussed above.

Referring now to FIG. 15I, frequency analyzing the first and second electrical load characteristics at the block 258 can include performing a Fourier transformation of the first and second electrical load characteristics at a block 278. Processing at the block 278 may be similar to that of the block 128 (FIG. 11J), discussed above.

Referring now to FIG. 15J, in some embodiments status of the at least one change in operational state of at least one electrical appliance of the at least one electrical circuit can be monitored at a block 280. Processing at the block 280 may be similar to that of the block 150 (FIG. 12A), discussed above.

Referring now to FIG. 15K, in some embodiments electrical appliances of the at least one electrical circuit can be identified based upon the difference in the frequency analyzed first and second electrical load characteristics at a block 282. Processing at the block 282 may be similar to that of the block 130 (FIG. 11K), discussed above.

Referring now to FIG. 15L, data indicative of identity of the identified electrical appliances of the at least one electrical circuit may be communicated at a block 284. Processing at the block 284 may be similar to that of the block 132 (FIG. 11L), discussed above.

Referring now to FIG. 15M, identifying electrical appliances of the at least one electrical circuit based upon the difference in the frequency analyzed first and second electrical load characteristics at the block 282 can include comparing the difference in the frequency analyzed first and second electrical load characteristics to a plurality of predetermined frequency analyzed electrical load characteristics for a plurality of predetermined electrical appliances at a block 286. Processing at the block 286 may be similar to that of the block 134 (FIG. 11M), discussed above.

### ILLUSTRATIVE APPLICATIONS AND NON-LIMITING EXAMPLES

Now that illustrative methods have been explained, some illustrative applications and non-limiting examples will be explained. It will be appreciated that the following applications and examples are given by of illustration and not of limitation.

Illustrative applications discussed below may entail various degrees of processing and/or analysis or the like. For example, data communicated from the system 30 by the communications system 50 may be received at an analysis facility that is separate from the location of the system 30 (or separate from the measurement location if the measurement is made remote from the remainder of components of the system 30). In some embodiments, data may be analyzed by a processor, such as a computer processor, or a signal analyzer or the like. In some other embodiments, data may be analyzed manually by a user. In such arrangements, the communicated data may be presented to the user via any suitable user-perceivable indicator as desired for a particular application, such as a video display, a light panel, individual light emitters, a sound producing device, or the like.

For example, in one approach patterns of usage may be identified from changes in operational state (which are identified based upon differences in frequency analyzed parameters or components thereof such as electrical load characteristics), and such patterns may be indicative of particular types of electrical appliances. As one example, large electrical current draws may correspond to compressor-type startup and, as such, may indicate that electrical appliances such as air-conditioners or refrigerators are part of an electrical circuit.

In other approaches with additional processing or pattern recognition (such as comparison of frequency analyzed parameters or components thereof to predetermined frequency analyzed parameters or components thereof for predetermined electrical appliances) a distinction can be made between or among types of electrical appliances, such as without limitation air-conditioners and refrigerators or between or among individual ones of such items.

As another example, differences from t₁ to t₂ in frequency analyzed parameters or components thereof such as electrical load characteristics that result in large increases in inductive components of electrical load characteristics (such as reactive power or susceptance) may indicate that motors are part of an electrical circuit. Alternately, differences from t₁ to t₂ in frequency analyzed parameters or components thereof such as electrical load characteristics that result in large decreases in inductive components of electrical load characteristics (such as reactive power or susceptance) may indicate that at least some motors are no longer part of an electrical circuit.

As another example, differences from t₁ to t₂ in frequency analyzed parameters or components thereof such as electrical load characteristics that result in large increases in capacitive components of electrical load characteristics (such as reactive power or susceptance) may indicate that power supplies or switched capacitive types of systems are part of an electrical circuit. Alternately, differences from t₁ to t₂ in frequency analyzed parameters or components thereof such as electrical load characteristics that result in large decreases in capacitive components of electrical load characteristics (such as reactive power or susceptance) may indicate that at least some power supplies or switched capacitive types of systems are no longer part of an electrical circuit.

As a further example, differences from t₁ to t₂ in frequency analyzed parameters or components thereof such as electrical load characteristics could indicate presence of high frequency jitter. Such differences could indicate presence within an electrical circuit of one or more electrical appliances such as a computer, a liquid crystal display, a plasma monitor, a high-definition television, or the like.

As a further example, differences from t₁ to t₂ in frequency analyzed parameters or components thereof such as electrical load characteristics could indicate presence of noisy 60 Hz electrical power. Such differences could indicate presence within an electrical circuit of one or more items such as a mercury vapor lamp, a hair dryer, a curling iron, or the like.

In some aspects, data indicative of operational state of electrical appliances or identity of electrical appliances that has been communicated and/or accessed and/or monitored may be used in a variety of fashions. For example, such data relating to a number of high current draw devices, or transient characteristics of such devices, can help improve predictive capability for power grid optimization.

In other aspects, data indicative of operational state of electrical appliances or identity of electrical appliances that has been communicated and/or accessed and/or monitored can help to inform restarts after power outages. Such data could also help to predict peak transient loads or for Monte Carlo modeling of events based upon factors such as synchronous activation of the maximum number of high current draw items or instabilities due to reactive loads simultaneously interacting with the power grid.

Alternatively, identification of patterns from changes in operational state can help to identify electrical appliances whose operating characteristics may have become degraded. In such an approach, it may be desirable to modify such operating characteristics (for example, replacement with higher efficiency items, replacement or repair of components that provide sub-optimal responses such as faulty filtering or high current draw motors). For example, in one approach identification of specific items may be coupled to a correction, such as offering replacement parts, offering sale of replacement parts or repair of equipment, or substitution of alternative types of items.

Illustrative Computer Program Products

In various embodiments, portions of the systems and methods include a computer program product. The computer program product includes a computer-readable storage medium, such as non-volatile storage medium, and computer-readable program code portions, such as a series of computer instructions, embodied in the computer-readable storage medium. Typically, the computer program is stored and executed by a processing unit or a related memory device, such as the processing components depicted in FIGS. 2A, 2B, 3A-3G, 4A, 4B, 5A, 5B, 6A, 6B, 7A, 7B, 8A, 8B, 9A, 9B, 10A, and 10B.

In this regard, FIGS. 2A, 2B, 3A-3G, 4A, 4B, 5A, 5B, 6A, 6B, 7A, 7B, 8A, 8B, 9A, 9B, 10A, 10B, 11A-11M, 12A-12J, 13A-13G, 14A-14M, and 15A-15M are block diagrams and flowcharts of systems, methods, and program products according to various embodiments. It will be understood that each block of the block diagram, flowchart and control flow illustrations, and combinations of blocks in the block diagram, flowchart and control flow illustrations, can be implemented by computer program instructions. These computer program instructions may be loaded onto a computer or other programmable apparatus to produce a machine, such that the instructions which execute on the computer or other programmable apparatus create means for implementing the functions specified in the block diagram, flowchart or control flow block(s). These computer program instructions may also be stored in a computer-readable memory that can direct a computer or other programmable apparatus to function in a particular manner, such that the instructions stored in the computer-readable memory produce an article of manufacture including instruction means which implement the function specified in the block diagram, flowchart or control flow block(s). The computer program instructions may also be loaded onto a computer or other programmable apparatus to cause a series of operational steps to be performed on the computer or other programmable apparatus to produce a computer implemented process such that the instructions which execute on the computer or other programmable apparatus provide steps for implementing the functions specified in the block diagram, flowchart or control flow block(s).

Accordingly, blocks of the block diagram, flowchart or control flow illustrations support combinations of means for performing the specified functions, combinations of steps for performing the specified functions and program instruction means for performing the specified functions. It will also be understood that each block of the block diagram, flowchart or control flow illustrations, and combinations of blocks in the block diagram, flowchart or control flow illustrations, can be implemented by special purpose hardware-based computer systems which perform the specified functions or steps, or combinations of special purpose hardware and computer instructions.

One skilled in the art will recognize that the herein described components (e.g., blocks), devices, and objects and the discussion accompanying them are used as examples for the sake of conceptual clarity and that various configuration modifications are within the skill of those in the art. Consequently, as used herein, the specific exemplars set forth and the accompanying discussion are intended to be representative of their more general classes. In general, use of any specific exemplar herein is also intended to be representative of its class, and the non-inclusion of such specific components (e.g., blocks), devices, and objects herein should not be taken as indicating that limitation is desired.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

With respect to the appended claims, those skilled in the art will appreciate that recited operations therein may generally be performed in any order. Examples of such alternate orderings may include overlapping, interleaved, interrupted, reordered, incremental, preparatory, supplemental, simultaneous, reverse, or other variant orderings, unless context dictates otherwise. With respect to context, even terms like “responsive to,” “related to,” or other past-tense adjectives are generally not intended to exclude such variants, unless context dictates otherwise.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1-167. (canceled)

168. A system comprising:
a measurement device configured to measure, at first and second times, first and second electrical power signals of at least one electrical circuit; and
a data processing system including:
a frequency analyzer configured to frequency analyze the measured first and second electrical power signals;
a first data processing component configured to compute components of first and second electrical load characteristics from the frequency analyzed measured first and second electrical power signals, respectively; and
a second data processing component configured to identify at least one change in operational state of at least one electrical appliance of the at least one electrical circuit based upon a difference in the components of the first and second electrical load characteristics.

169. The system of claim 168, further comprising a communications system configured to communicate data indicative of the at least one change in operational state of at least one electrical appliance of the at least one electrical circuit.

170. The system of claim 169, wherein the communications system includes a power line carrier communication system.

171. The system of claim 169, wherein the communications system includes a wireless communication system.

172. The system of claim 169, wherein the communications system includes a network communication system.

173. The system of claim 168, further comprising data storage configured to store data indicative of the at least one change in operational state of at least one electrical appliance of the at least one electrical circuit.

174. The system of claim 173, wherein the data storage is removable.

175. The system of claim 168, wherein the measurement device includes at least one current measurement device.

176. The system of claim 175, wherein the current measurement device includes at least one current transformer.

177. The system of claim 175, wherein the current measurement device includes at least one ammeter.

178. The system of claim 168, wherein the measurement device includes at least one voltage measurement device.

179. The system of claim 168, wherein the frequency analyzer implements a fast Fourier transform.

180. The system of claim 168, wherein the data processing system includes a third data processing component that is configured to identify electrical appliances of the at least one electrical circuit based upon the difference in the components of the first and second electrical load characteristics.

181. The system of claim 180, further comprising a communications system configured to communicate data indicative of identification of the identified electrical appliances.

182. The system of claim 180, further comprising data storage that stores a plurality of predetermined components of electrical load characteristics for a plurality of predetermined electrical appliances.

183. The system of claim 168, wherein the measurement device is disposed at a location within the electrical circuit.

184. The system of claim 168, wherein the measurement device is disposed at a location that is electrically proximate to an isolation point of the electrical circuit.

185. The system of claim 168, wherein the measurement device is disposed at an electrical service entrance that supplies the at least one electrical circuit.

186. The system of claim 168, wherein the measurement device is disposed at a power line between an electric utility and an electrical service entrance that supplies the at least one electrical circuit.

187. The system of claim 168, wherein the electrical load characteristics include at least one power component chosen from real power and reactive power.

188. The system of claim 168, wherein the electrical load characteristics include at least one admittance component chosen from conductance and susceptance.

189. The system of claim 168, wherein the frequency analyzer is configured to analyze the fundamental frequency component of the first and second electrical power signals.

190. The system of claim 168, wherein the frequency analyzer is configured to analyze at least one non-fundamental harmonic frequency component of the first and second electrical power signals.

191. The system of claim 190, wherein the at least one non-fundamental harmonic frequency component includes at least one odd non-fundamental harmonic frequency component.

192. The system of claim 191, wherein the at least one odd non-fundamental harmonic frequency component includes a third harmonic frequency component.

193. A system comprising:
a measurement device configured to measure, at first and second times, first and second electrical power signals of at least one electrical circuit; and
a data processing system including:
a first data processing component configured to compute first and second electrical load characteristics from the measured first and second electrical power signals, respectively;
a frequency analyzer configured to frequency analyze the first and second electrical load characteristics; and
a second data processing component configured to identify at least one change in operational state of at least one electrical appliance of the at least one electrical circuit based upon a difference in components of the first and second electrical load characteristics.

194. The system of claim 193, further comprising a communications system configured to communicate data indicative of the at least one change in operational state of at least one electrical appliance of the at least one electrical circuit.

195. The system of claim 194, wherein the communications system includes a power line carrier communication system.

196. The system of claim 194, wherein the communications system includes a wireless communication system.

197. The system of claim 194, wherein the communications system includes a network communication system.

198. The system of claim 193, further comprising data storage configured to store data indicative of the at least one change in operational state of at least one electrical appliance of the at least one electrical circuit.

199. The system of claim 198, wherein the data storage is removable.

200. The system of claim 193, wherein the measurement device includes at least one current measurement device.

201. The system of claim 200, wherein the current measurement device includes at least one current transformer.

202. The system of claim 200, wherein the current measurement device includes at least one ammeter.

203. The system of claim 193, wherein the measurement device includes at least one voltage measurement device.

204. The system of claim 193, wherein the frequency analyzer implements a fast Fourier transform.

205. The system of claim 193, wherein the data processing system includes a third data processing component that is configured to identify electrical appliances of the at least one electrical circuit based upon the difference in the components of the first and second electrical load characteristics.

206. The system of claim 205, further comprising a communications system configured to communicate data indicative of identification of the identified electrical appliances.

207. The system of claim 205, further comprising data storage that stores a plurality of predetermined components of electrical load characteristics for a plurality of predetermined electrical appliances.

208. The system of claim 193, wherein the measurement device is disposed at a location within the electrical circuit.

209. The system of claim 193, wherein the measurement device is disposed at a location that is electrically proximate to an isolation point of the electrical circuit.

210. The system of claim 193, wherein the measurement device is disposed at an electrical service entrance that supplies the at least one electrical circuit.

211. The system of claim 193, wherein the measurement device is disposed at a power line between an electric utility and an electrical service entrance that supplies the at least one electrical circuit.

212. The system of claim 193, wherein the electrical load characteristics include at least one power component chosen from real power and reactive power.

213. The system of claim 193, wherein the electrical load characteristics include at least one admittance component chosen from conductance and susceptance.

214. The system of claim 193, wherein the frequency analyzer is configured to analyze the fundamental frequency component of the first and second electrical load characteristics.

215. The system of claim 193, wherein the frequency analyzer is configured to analyze at least one non-fundamental harmonic frequency component of the first and second electrical load characteristics.

216. The system of claim 215, wherein the at least one non-fundamental harmonic frequency component includes at least one odd non-fundamental harmonic frequency component.

217. The system of claim 216, wherein the at least one odd non-fundamental harmonic frequency component includes a third harmonic frequency component.

218-308. (canceled)
